(19) United States
(12) Patent Application Publication
(10) Pub. No.: US 2014/0287264 A1
(43) Pub. Date: Sep. 25, 2014

(54) ORDERED STACKED SHEETS OF LAYERED INORGANIC COMPOUNDS, NANOSTRUCTURES COMPRISING THEM, PROCESSES FOR THEIR PREPARATION AND USES THEREOF

(71) Applicant: YEDA RESEARCH AND DEVELOPMENT CO. LTD., Rehovot (IL)

(72) Inventors: Reshef Tenne, Rehovot (IL); Gal Radovsky, Rehovot (IL); Ronit Popovitz-Biro, Rehovot (IL)

(73) Assignee: YEDA RESEARCH AND DEVELOPMENT CO. LTD., Rehovot (IL)

(21) Appl. No.: 14/352,404

(22) PCT Filed: Oct. 18, 2012
(86) PCT No.: PCT/IL2012/050412

§ 371 Date: Apr. 17, 2014

Related U.S. Application Data
(60) Provisional application No. 61/549,358, filed on Oct. 20, 2011.

(51) Int. Cl. B01J 27/02; H01L 29/06; H01B 1/18; B01J 35/00

(52) U.S. Cl. CPC B01J 27/02; B01J 35/004; H01L 29/0665; H01B 1/18; Y10S 977/762; Y10S 977/814; Y10S 977/891; B82Y 40/00
USPC 428/699; 502/216; 502/100; 427/248.1; 977/762; 977/814; 977/891

(57) ABSTRACT

Provided is a nanostructure including ordered stacked sheets and processes for its preparation and use.

### FIELD OF THE INVENTION

This invention relates to nanostructures comprising sheets of layered inorganic compounds, processes for their preparation and uses thereof.

### BACKGROUND OF THE INVENTION

Nanoparticles of layered compounds are unstable in the planar form, forming closed polyhedral inorganic fullerene-like (IF) nanoparticles and also inorganic nanotubes (INT). Their formation is attributed to the annihilation of the dangling bonds of the rim atoms.

INT of misfit layered chalcogenide compounds (such as (PbS)₁₊ₓ(NbS₂)ₙ and (BiS)₁₊ₓ(NbS₂)ₙ) were reported in the literature (J. Rouxel et al. J. Alloys Comp. 1995, 229, 144-157 and D. Bernaerds et al. J. Cryst Growth 1997, 172, 433-439).

The alternate stacking of MX and TX₂ (M=Sn, Pb, Sb, Bi and rare earth metals, T=Sn, Ti, V, Cr, Nb, Ta; X=S, Se) in misfit layered compounds is thought to be stabilized also by a partial charge transfer (CT) from the MX layer to the TX₂ layer.

### SUMMARY OF THE INVENTION

The present invention provides a nanostructure comprising ordered stacked sheets comprising: at least one first sheet of an inorganic layered compound of general formula MXₙ; and at least one second sheet of an inorganic layered compound of formula M′Xₘ;

wherein M and M′ are each selected from a group consisting of Sn, In, Ga, Bi, Ta, W, Mo, V, Zr, Hf, Pt, Re, Nb, Ti and Ru; X is selected from S, Se and Te; n and m are integers being independently 1 or 2; wherein said stacked at least one first sheet and at least one second sheet have mismatched lattice structure. In some embodiments A M and M′ are each selected from a group consisting of Nb, Sn and Pb. In some embodiments M and M′ are the same. In other embodiments M and M′ are different.

The term “nanostructure” is meant to encompass any three dimensional structure having at least one dimension in the nanometer scale (i.e. between 0.1 and 100 nm). According to the present invention a nanostructure comprises sheets of at least one first sheet of an inorganic layered compound of general formula MXₙ; and at least one second sheet of an inorganic layered compound of formula M′Xₘ, wherein said sheets are stacked in an ordered configuration. In some embodiments, said nanostructure is selected from a nanotube, a nanoscroll, a nanocage, or any combination thereof.

The term “inorganic layered compound” is meant to encompass inorganic compounds (i.e. which do not consist of carbon atoms), capable of being arranged in stacked atomic layers, forming two dimensional sheets (i.e. sheet of an inorganic layered compound). While the atoms in within the layers are held by strong chemical bonds, weak van der Waals interactions hold the layers together. For example, for an inorganic layered compound such as SnS₂, it was observed that each molecular layer of SnS₂ consists of a six fold-bonded tin layer “sandwiched” between two three-fold bonded sulphur layers, thus forming a sheet of SnS₂. α-SnS (herzenbergite) has a GeS structure with an orthorhombic (pseudo tetragonal highly distorted NaCl) unit cell (a=1.118 nm, b=0.398 nm, c=0.432 nm Pnma). Each tin atom is coordinated to six sulfur atoms in a highly distorted octahedral geometry. There are two corrugated tin sulfide double layers in a unit cell composed of tightly bound Sn—S atoms, the layers are stacked together by weak van der Waals forces.

In some embodiments, said at least one first sheet has the general formula (MXₙ)ₚ; wherein p is an integer selected from 1-5, i.e. said first sheet of inorganic layered compound MXₙ is formed of p molecular layers of MXₙ. In further embodiments, said at least one second sheet has the general formula (M′Xₘ)_{q}; wherein q is an integer selected from 1-5; i.e. said second sheet of inorganic layered compound M′Xₘ is formed of q molecular layers of M′Xₘ.

The term “ordered stacked sheets” (or “ordered stacked configuration”) relates to the arrangement of the sheets of an inorganic layered compound in a nanostructure of the invention. According to the present invention, said at least one first sheet of an inorganic layered compound of general formula MXₙ is stacked on top of said at least one second sheet of an inorganic layered compound of general formula M′Xₙ, (or vice versa, i.e. said at least one second sheet of an inorganic layered compound is stacked on top of said at least one first sheet of an inorganic layered compound). The stacked sheets are held together via van der Waals forces. The molecular “rims” at the edges of such inorganic layered materials are capable of being folded to form stable nanostructures wherein most of the inorganic atoms are fully bonded.

The order of the stacked sheets of a nanostructure of the invention includes any repeating arrangement of said first sheet (F) and second sheet (S), such as for example ( . . . FSFSFS . . . ), ( . . . FFSFFSFFS . . . ), ( . . . SSFSSFSSF . . . ), ( . . . SSFFSSFF . . . ), ( . . . FFSSFFSS . . . ) or any combination thereof.

Therefore, in some embodiments, said nanostructure has the general formula [(MXₙ)ₚ(M′Xₘ)_{q}]ᵣ, wherein r is an integer selected from 1-100. Thus, a nanostructure of the invention is formed by repeating an ordered stacked unit of (MXₙ)ₚ(M′Xₘ)_{q} r times. In some embodiments r is an integer selected from 10, 20, 30, 40, 50, 60, 70, 80, 90, 100.

The term “mismatched lattice structure” is meant to encompass any degree of misfit between the lattice structures (crystalline morphology) of said at least one first sheet of an inorganic layered compound and said at least one second sheet of an inorganic layered compound. The lattice structures of said first and second sheets incommensurate by at least one axis and/or at least one angle of the unit cells of the lattices (e.g. by at least one of axes a, b or c and or at least one axes angles α, β or γ of the unit cells, namely Bravais lattices, of each sheet of the inorganic layered compound). In some other embodiments, the lattice structures of said first and second sheets incommensurate by at least two axes of the unit cells of the lattices. For example, said first sheet has an orthorhombic morphology and said second sheet has a trigonal morphology.

In some embodiments each X in MXₙ and M′Xₘ is independently selected from S, Se and Te.

In other embodiments, n=1 and m=2. Thus said nanostructure has a formula [(MX)ₚ(MX₂)_{q}]ᵣ, wherein p, q and r are as defined herein above.

In further embodiments, M is Sn. In other embodiments, X is S. In yet other embodiments, X is Se.

In other embodiments, p=q=1. Thus, said nanostructure has a formula [(MXₙ)(M′Xₘ)]ᵣ, wherein n, m and r are as defined herein above.

In other embodiments, wherein p=1 and q=2. Thus, said nano structure has a formula [(MXₙ)(M′Xₘ)₂]ᵣ, wherein n, m and r are as defined herein above.

According to some embodiments of the invention, said sheets of an inorganic layered compound (i.e. at least one of at least one first and at least one second sheets defined hereinabove) are closed sheets (i.e., closure of dangling bonds at the periphery of the layers, thus forming a closed nanostructure). Under these embodiments, said nanostructure is a nanotube.

In a further aspect the invention provides a nanostructure comprising: at least one first sheet comprising an inorganic layered compound of the formula MXₙ; at least one second sheet comprising an inorganic layered compound of the formula M′Xₘ;

wherein said sheets have mismatched lattice structures and are arranged in an ordered stacked configuration, thereby forming said nanostructure of the general formula (I):

[(MXₙ)ₚ(M′Xₘ)_{q}]ᵣ (I)

wherein M and M′ are each selected from a group consisting of Sn, In, Ga, Bi, Ta, W, Mo, V, Zr, Hf, Pt, Re, Nb, Ti and Ru; X is selected from S, Se and Te; each of n and m is independently for 2; each of p and q is independently selected from 1-5; and r is an integer selected from 1-100.

In another aspect, the invention envisages an article comprising at least one nanostructure comprising multiple ordered stacked sheets, as defined herein above. In some embodiments said article is selected from a transistor, a solar cell, an electrode, a photo-catalyst.

In a further aspect, the invention provides a process for the preparation of a nanostructure comprising multiple ordered stacked sheets, as defined herein above, said process comprising:
(a) Providing at least one inorganic compound selected from MXₙ and M′Xₘ;
(b) Vaporizing said at least one inorganic compound in the presence of at least one first catalyst at a vaporizing temperature (Tₐ);
(c) Maintaining said vaporized at least one inorganic compound in a temperature gradient formed between a hot zone of temperature Tₐ and a cold zone of temperature T_{b} thereby forming said nanostructure in said cold zone.

The term “inorganic compound” relates to any compound which does not contain any carbon atoms, capable of forming a layered structure, when employed in a process of the invention. Said inorganic compound may be provided in crystalline forms. In other embodiments of a process of the invention, said at least one inorganic compound is SnS₂, thereby forming a nanostructure of the formula [(SnSₙ)ₚ(SnSₘ)_{q}]ᵣ wherein n, m, p, q are as defined herein above.

Vaporizing said at least one inorganic compound (step (b)) is performed at a temperature (T_{Q}) allowing the inorganic compound to form a gaseous species. In some embodiments of a process of the invention, said Tₐ is in the range of between about 700-850° C. In other embodiments of a process of the invention, temperature Tₐ in step (b) is maintained for more than 1 h. In a further embodiments, temperature Tₐ in step (b) is maintained for a period of about 1 to 2 h.

Said at least one first catalyst enables the formation of said first and second sheets of layered compounds MXₙ and M′Xₘ forming the nanostructure of the invention. In some embodiments of a process of the invention said vaporization of said at least one inorganic compound is performed in the presence of at least one second catalyst. In some embodiments of a process of the invention, said first catalyst is Bi. In other embodiments of a process of the invention said second catalyst is selected from Sb₂S₃ and Sb₂Se₃.

In step (c) of the process of the invention said vaporized at least one inorganic compound is maintained for a predetermined period of time in a temperature gradient formed between a hot zone and a cold zone, thereby enabling the formation of said nanostructure in said cold zone. In some embodiments, an inorganic compound is provided in a closed receptacle (for example an ampoule or tube), which is then exposed to a vaporizing temperature (Tₐ), thus forming vapors of said inorganic compound. Thereafter, one end of said receptacle is maintained at temperature Tₐ while the other end of said receptacle is exposed to a lower temperature T_{b}, thereby exposing said vaporized inorganic compound within the receptacle to a temperature gradient.

In other embodiments the inorganic compound is placed in a reactor having a hot zone of temperature Tₐ, thus vaporizing said inorganic compound. Said vaporized inorganic compound is flowed (by using for example Ar gas flow) into a cold zone having temperature T_{b}.

In other embodiments, T_{b} is in the range of between about 300-100° C.

In other embodiments, said vaporized at least one inorganic compound is maintained in temperature gradient of step (c) between about 30 min to 1.5 h.

### BRIEF DESCRIPTION OF THE DRAWINGS

In order to understand the invention and to see how it may be carried out in practice, embodiments will now be described, by way of non-limiting example only, with reference to the accompanying drawings, in which:

FIGS. 1A-1B. is a schematic illustration of Orthorhombic α-SnS (Pnma)-Herzenbergite, with a=1.118 nm, b=0.398 nm, c=0.432 nm (FIG. 1A) and Pseudohexagonal (trigonal) (P3m1) 2H—SnS₂ with a=b=0.36486 nm, c=0.58992 nm (FIG. 1B).

FIG. 2 is a depiction of SnS₂/SnS ordered tubular structures. Pseudo-hexagonal trigonal (T) SnS₂ and orthorhombic (O) SnS layers with interlayer spacing of 0.59 nm and 0.56 nm respectively, relax misfit stress by forming tubular scrolls and closed nanotubes.

FIG. 3 is a schematic illustration of the different stacking orders of SnS₂ and SnS layers along their common c-axis.

FIG. 4 is a schematic illustration of the relative in-plane orientation between the SnS₂ and SnS layers within O-T tubule. Single basal SnS₂ layer is projected along normal to (10.0) planes and single basal SnS layer is projected along the normal to (011) planes. Both the normals are parallel. Left images show a projections along the direction perpendicular to the basal planes.

FIG. 5 is a schematic illustration of the relative in-plane orientations within the O-T-T slab between the SnS, SnS₂ and additional SnS₂ layers which have a common “c-axis”. The layers are projected along the normals to the planes as indicated. Left images show a projections along the direction perpendicular to the basal planes

FIG. 6A is a high magnification backscattering electrons (BSE) SEM image illustrating the exfoliation/scrolling of SnS₂/SnS misfit layers into tubular (scroll) structures. Sulfides of bismuth appear as bright spots in the BSE contrast; FIG. 6B is a secondary electrons (SE) image of tubule's agglomerate. Red arrows indicate nanosheets in the midst of a scrolling process. Blue arrows point to nanoscrolls exhibiting helical wound growth step which can be clearly seen in the inset and is marked by short white arrows; FIG. 6C is a SE image of macroscopic amounts of nanotubes, nanoscrolls and several unscrolled nano sheets.

FIG. 7 shows a hypothetical model illustrating the catalytic action of Bi in the creation of sulfur deficient SnS₂/SnS superstructures with Bi₂S₃ inclusions.

FIGS. 8A-8D show the evolution of SnS₂/SnS ordered superstructure nanotubes/nanoscrolls growth in evacuated ampoules via the catalytic action of Bi and Sb₂S₃. FIG. 8A is a low magnification backscattered electrons (BSE) SEM image of SnS₂ platelet attacked by Bi and Sb₂S₃ and partially converted to nanotubes/nanoscrolls; FIG. 8B is a medium magnification (BSE) image illustrating the exfoliation and folding of the superstructure sheets. In both FIGS. 8A and 8B sulfides of bismuth appear as bright spots. FIG. 8C is a low magnification secondary electrons (SE) image of SnS₂ platelet in early stages of conversion into the nanotubes. FIG. 8D shows a low magnification SE image of almost fully converted SnS₂ platelet to SnS₂/SnS tubules.

FIGS. 9A-9D shows the low (9A) and high (9B-9D) magnifications SEM images of a “hedgehog”-like agglomerate of SnS₂—SnS tubules with different internal structure and morphology. The scrolling process is shown in 9D.

FIGS. 10A-10G provide TEM image of a tubule with partly unrolled superstructured sheet. (10A) Low magnification image. (10B) High magnification and (10C) SAED pattern obtained from area marked as “1” in (10A). The inset in (10B) is a fast Fourier transform (FFT) of the image in 10B. 10D shows relative in-plane orientation between the SnS2 and SnS layers. Single basal SnS2 layer is projected along normal to (10.0) planes and single basal SnS layer is projected along the normal to (011) planes. Both normals are parallel. Panel (10E) shows a high magnification image obtained from area marked as “2” in panel (10A). Panel (10F) is a line profile integrated along the region enclosed in the rectangle in panel (10E). (10G) SAED pattern obtained from the area in (10E). For both (10C) and (10G), spots pertinent to the same interplanar spacing are marked by dotted rings and their measured values and pertinent Miller indices are indicated. Red circles correspond to SnS2 and green to SnS.

FIGS. 11A-11D provides (11a) Medium and (11b) high magnification TEM images of SnS2-SnS tubule with O-T . . . periodicity. (c) Line profile integrated along the region enclosed in the rectangle in (11b). (11d) SAED pattern taken from the area shown in (a). Tubule axis is marked by a pink double arrow. Red and green double arrows point on spots of SnS2 and SnS used for determination of the chiral angles. Blue arrows indicate on a basal reflection produced from a superstructure with their adjacent satellite spots. One reflection (002 of the superstructure) with its satellites is surrounded by a blue oval loop. Orange arrows indicate one couple of 20.0 reflections of SnS2.

FIGS. 12A-12D provides (12a) High and low (inset) magnification TEM images of SnS2/SnS tubule with O-T-T . . . periodicity. (12b) Line profile integrated along the region enclosed in the rectangle in (12a). (12c) SAED pattern taken from the area shown in (12a). Tubule axis is marked by a pink double arrow. Red and green double arrows point on spots of SnS2 and SnS used for the determination of the chiral angles. Blue arrows indicate to a basal reflection produced from a superstructure. Panel (12d) shows relative in-plane orientations within the O-T-T slab between the SnS, SnS2, and additional SnS2 layers which have a common “c-axis”. The layers are projected along the normals to the planes as indicated. The layers are slightly inclined to illustrate the three-dimensional structure.

FIGS. 13A-13C provide (13a) High and low (inset) magnification TEM images of SnS2/SnS tubule with O-T-O-T-T . . . periodicity. (13b) Line profile integrated along the region enclosed in the rectangle in (13a). (13c) SAED pattern taken from the area shown in (13a). Tubule axis is marked by a pink double arrow. Red and green double arrows point on spots of SnS₂ and SnS used for determination of the chiral angles. Blue arrows indicate on a basal reflection produced from a superstructure.

FIGS. 14A-14B provide low (14a) and high (14b) magnification TEM images of “telescopic structure” tubules with growing steps.

FIGS. 15A-15B provide (15a) High magnification TEM image of a cross sectional view of an O-T-T . . . nanoscroll that is aligned parallel to the electron beam and is a part of small tubular agglomerate (15b). The tubule shown in (15a) is marked by red arrow in (15b). The inset in (15a) is a line profile integrated along the region enclosed in the rectangle; however, imaging geometry of that specific tubule prevents the acceptance of a high resolution image, therefore the double peak observed for the two corrugated SnS layers can not be observed and appears like one wide peak.

FIGS. 16A-16C provide (16a) High and low (inset) magnification TEM images of a conical nanoscroll with T-T-O . . . periodicity. Red and blue segmented lines are tangential to the basal fringes at two opposing walls of the tubule, while continuous ones are perpendicular respectively. The angle between the latter equals to the projected angle of the cone. (16b) Line profile integrated along the region enclosed in the rectangle in (16a). (16c) SAED pattern taken from the area shown in (a). Blue segmented lines indicate to two arrays of basal reflections, azimuthally splintered by an angle equal to the projected apex angle of the cone.

FIG. 17 depicts the temperature profile along the 1-zone vertical furnace used for the synthesis of tubular structures in sealed ampoules. The position of the ampoule is shown in each step of the synthesis.

FIGS. 18A-18B shows a low (18A) and high (18B) magnification TEM images of the annealed SnS₂—SnS tubular structures.

FIGS. 19A-19B are schematic representations of the horizontal reactor (FIG. 9A) and vertical reactor (FIG. 9B)

FIGS. 20A-20B are high magnification images of nanotubes obtained in a horizontal flow system: FIG. 20A shows T-O . . . ordered superstructure nanotube taken from area T₄; FIG. 20B shows almost pure SnS₂ nanotube (besides the three innermost T-O layers) taken from area T₁.

FIG. 21 shows a temperature profile along the 2-zone furnace used for the synthesis of tubular structures in sealed ampoules. The position of the ampoule is shown in each step of the synthesis.

FIGS. 22A-22C shows a 200 μm (FIG. 22A), 1 μm (FIG. 22B) and 2 μm (FIG. 22C) magnification SEM images of the produced nanotubes utilizing Sb₂Se₃ as a co-catalyst.

FIG. 23 is a typical EDS spectrum obtained from most of the nanotubes utilizing Sb₂Se₃ as a co catalyst. Typical peaks of Se are marked in red ovals.

FIG. 24 is a HRTEM image of a defected tubule SnS₂/SnS tubule which contains a few percent of Se. The defects are marked in ovals.

### DETAILED DESCRIPTION OF EMBODIMENTS

Misfit layered compounds (MX)₁₊ₓ(TX₂)ₘ (with M=Sn, Pb, Sb, Bi, rare earths; T=Sn, Ti, V, Cr, Nb, Ta; X=S, Se; 0.08<x<0.32; m=1, 2, 3) have a planar composite structure, composed of two layered subsystems, namely, MX and TX₂. Alternating layers of the two subsystems are stacked along the common “c-axis” forming a superstructure. The MX slab has a pseudotetragonal symmetry which consists of a two-atom-thick {001} slice of a rock-salt-like (distorted NaCl) structure. The pseudo hexagonal TX₂ sandwich is a three-atom-thick structure in which the transition metal T is surrounded by six chalcogen atoms, either in octahedral coordination (T=Sn, Ti, V, Cr) or in a trigonal prismatic coordination (T=Nb, Ta). Note that bulk VS₂ and CrS₂ are metastable at room temperature and become stable as a part of a “misfit” lattice. Incommensurate behavior arises from the irrational ratio of the in-plane lattice parameters of the two subsystems along at least one direction a or b at the MX-TX₂ interface. The common c-axis is perpendicular to the layers.

In the case of the (SnS)₁₁₇/NbS₂ misfit compound, SnS adopts a distorted NaCl structure with lattice parameters of a=5.673, b=5.751, c=11.761 Å with a space group of Cm2a which is different from the most commonly synthesized bulk α-SnS with space group Pnma (known as Herzenbergite). The NbS₂ adopts pseudo hexagonal structure with an ortho-hexagonal unit cell of a=3.321, b=√3×3.321=5.752, c=11.761 Å and Cm2m space group. Corresponding axes are parallel, and the lattice parameters of the two subsystems fit along the b axes, while along the a axes they are incommensurate. Almost similar behavior can be found in the (PbS)_{1.14}NbS₂ system.

Misfit layered compounds are suitable candidates to form tubular structures. An example for such nanotubes in the “mistfit” pair PbS—NbS₂. The tendency for the folding of the layers is attributed to the difference in the lattice parameters, between the two lamellae, the bending axis being perpendicular to the direction along which the lattice parameters differ mostly. Upon bending the convex upper layer is subjected to a tensile stress while the lower (inner) concave layer is under compression strain. This situation leads to reduced differences between the lattice parameters of the two layers and hence the strain energy is reduced. The tubule axis is expected to coincide with the commensurate b direction. Surprisingly, most of PbS_{1.14}(NbS₂)₂ tubes were found to be chiral. This fact was attributed to the small misfit between the b axes of the pristine compounds which accommodates elastically and causes the axis of curvature to deviate somewhat from the “commensurate” direction, that is, lead to chiral tubes. In the SnS₂—SnS system incommensurate behavior is believed to be present along both directions of the basal planes of the two subsystems.

Tubular Structures of Micas.

Another example for the appearance of tubular structures in asymmetric layered crystals is the case of micas. In the case of asymmetric chrysotile, halloysite, and imogolite, different surface tensions of the asymmetric sheet surfaces, promote the formation of a curved structure. The strain energy was shown to fit the Eₛₜᵣ=a/r²+b/r relationship, where r is the tube radius and a and b are constants. Since b is negative, the energy function exhibits a distinct minimum which results in a narrow distribution of nanotube-diameter. Alternately, such a bending can be explained by taking into account the difference in the a₀ and b₀ unit cell parameters of the silicon oxygen (tetrahedral) sheet and the aluminum/magnesium hydroxyl (octahedral) sheet.

Sn—S System.

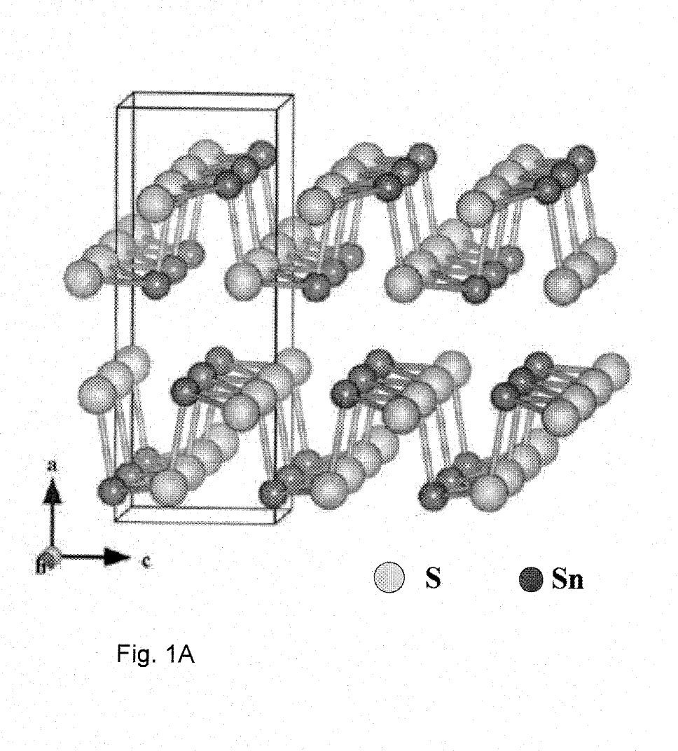

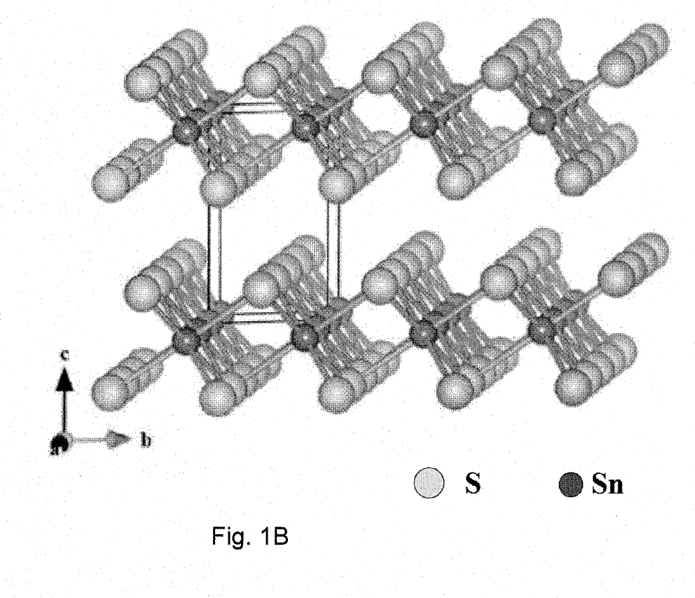

The present discussion is limited to the α-allotrops of the two compounds α-SnS and α-SnS₂ which possess a layered structure. α-SnS (Pnma), the bulk phase also termed Herzenbergite, has a GeS structure with an orthorhombic (pseudo tetragonal highly distorted NaCl) unit cell as shown in FIG. 1A. The lattice parameters of this phase are a=1.118 nm, b=0.398 nm, c=0.432 nm. Each tin atom is coordinated to six sulfur atoms in a highly distorted octahedral geometry. There are two corrugated tin sulfide double layers in a unit cell composed of tightly bound Sn—S atoms, the layers are stacked together by weak van der Waals forces. α-SnS₂ (P3ml) crystallizes in the CdI₂ layered structure with a pseudo hexagonal unit cell (sometimes referred as trigonal), in which the tin atoms are located in octahedral sites between two hexagonally close packed sulfur slabs to form a three-atom layered sandwich structure as shown in FIG. 1B. The coordination number of the metal and the sulfur atoms are 6 and 3, respectively. More than 70 polytype structures of SnS₂ have been identified. The polytypism arises from different stacking of the 2-D molecular layers. The simplest polytype of SnS₂ is designated either 1T or 2H depending on the system of labeling, with a=0.36486 nm, c=0.58992 nm, and one sulfur-metal-sulfur triple layer as a repeat unit. The interatomic interaction within the layers is much stronger than the interaction between the layers. The SnS₂ layers are held together by weak van der Waals forces allowing the crystals to be easily cleaved perpendicular to the c-axis. The present paper presents a study of the tubular structures of the SnS—SnS₂ misfit compound with precise stoichiometry of (SnS)_{1.32}(SnS₂), (SnS)_{1.32}(SnS₂)₂, and [(SnS)_{1.32}]₂[(SnS₂)]₃.

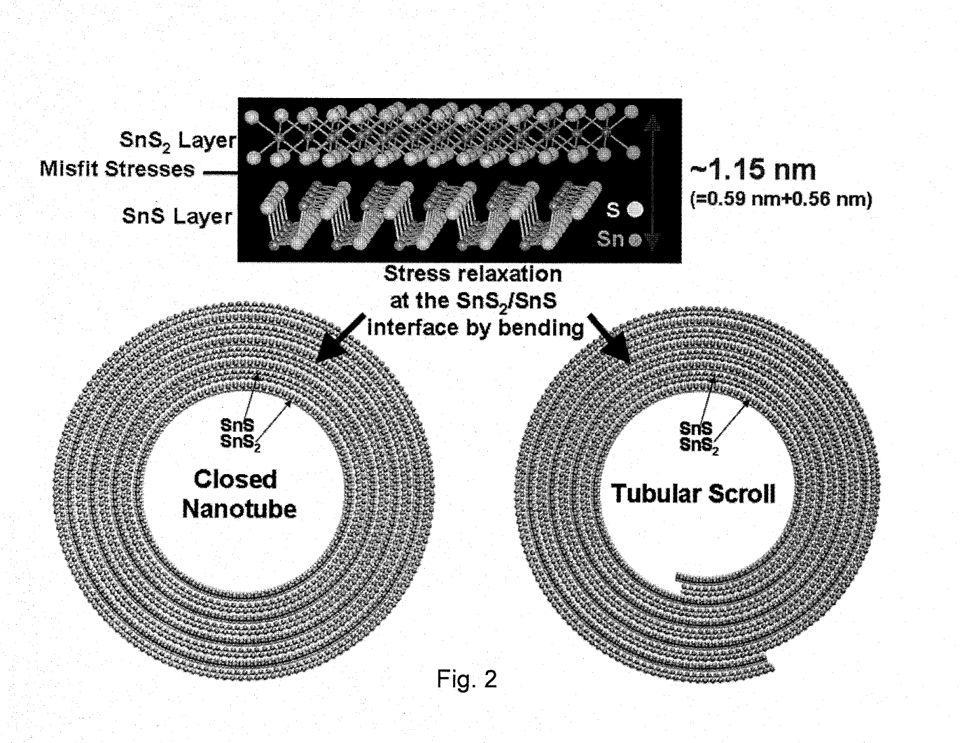

The Sn—S system can be regarded as a misfit layered compound and the tubular morphology is a result of the lattice mismatch between the two alternating layers of SnS₂ and SnS sublattices (i.e. crystalline structures), which leads to intrinsic stress in the SnS₂/SnS superstructure sheets. This driving force comes in addition to the closure mechanism, i.e., annihilation of dangling bonds at the periphery of the layers of the INT nanostructures. Combination of the above-mentioned driving forces leads to the formation of nanoscroll and nanotube morphologies as shown in FIG. 2. Furthermore, in analogy to chrysotile (asbestos) nanotubes, the driving force for the formation of nanotubes of misfit compounds stems from the asymmetry along the c-axis of the unit cell.

The tubular morphology is a result of the lattice mismatch between the two sublattices forming internally stressed superstructure sheets with several stacking order possibilities. However, spontaneous bending is mostly expected for an asymmetric lamella, that is, limited on one side by a SnS and on the other side by a SnS₂ layer. This driving force is complementary to the already established closure mechanism, that is, annihilation of the dangling bonds at the periphery of the layers of the inorganic nanotubes (INT) nanostructures. The Raman spectrum obtained from the SnS₂—SnS tubules, is almost a superposition of the Raman modes of the individual layers, indicating weak interlayer interactions, which facilitates bending of the layers. Tubular crystals can be classified in two main groups: scrolllike or nanoscrolls and tube-like or nanotubes. In nanoscrolls, one sheet scrolls several times forming a helical or non helical scroll. Scrolls can be cylindrical or rather conical. In nanotubes every layer is closed on itself; chemically independent of the adjacent layers. Weak van der Waals forces are present between the layers.

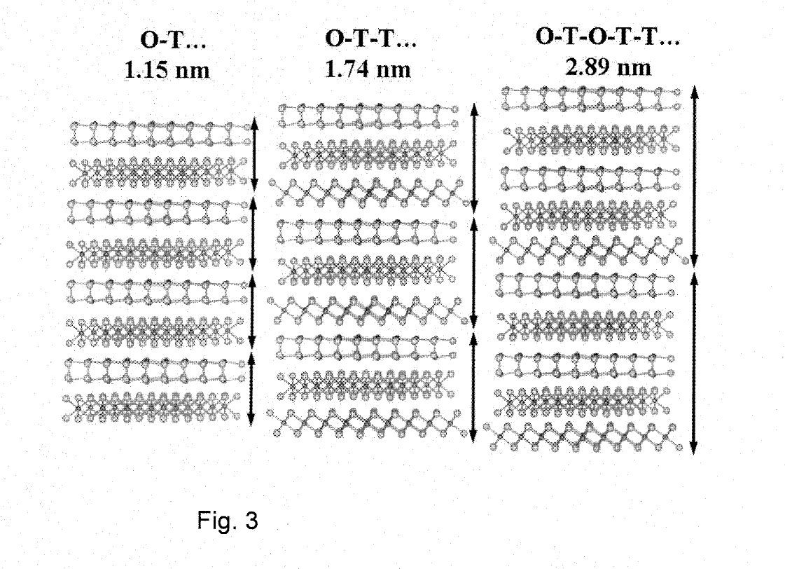

Pseudo-hexagonal trigonal (T) SnS₂ and orthorhombic (O) SnS layers, relax misfit stress by forming tubular scrolls and closed nanotubes. Different in-plane orientations between the SnS₂ and SnS are schematically illustrated. Extensive statistical structural analysis was performed on a large amount of the tubular structures of SnS₂—SnS tubules by HRTEM and electron diffraction. In the majority of cases, ordered superstructure tubules with asymmetric layer stacking of (O-orthorhombic) SnS, and (T-trigonal) SnS₂ in a sequence O-T . . . could be observed with lattice spacing of 1.15 (0.56+0.59) nm and precise stoichiometry of (SnS)_{1.32}(SnS₂) or O-T-T . . . with lattice periodicity of ˜1.74 (0.56+0.59+0.59) nm along the common “c-axis” and stoichiometry of (SnS)_{1.32}(SnS₂)₂. Tubes with a periodicity of O-T-O-T-T . . . with lattice spacing of 2.89 (0.56+0.59+0.56+0.59+0.59) nm and stoichiometry of [(SnS)_{1.32}]₂[(SnS₂)]₃ were also encountered, albeit rarely as shown in FIG. 3.

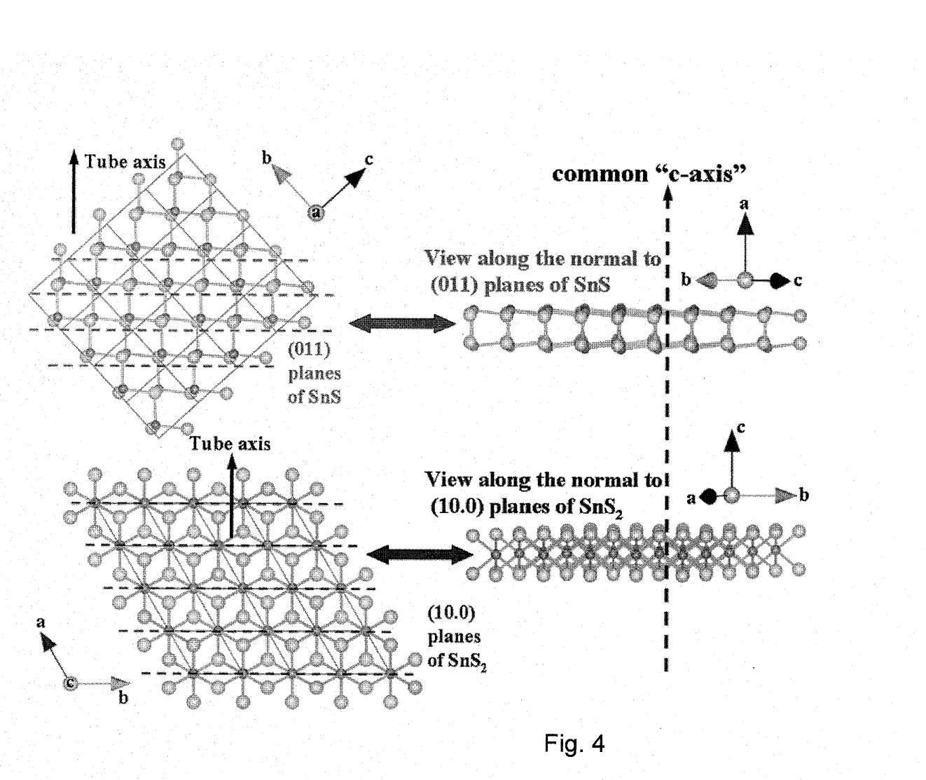

Tubes having random stacking order were also sporadically encountered. The periodicity of the superstructure can be determined from the diffraction patterns, i.e. from the distance between two adjacent basal reflections of order “n” and “n+1”. Such an analysis also suggests that in all cases both SnS₂ and SnS layers have a common “c-axis”. As for their in planar orientation, in most cases the normal to the (10.0) planes of SnS₂ is parallel/almost parallel to the normal to the (011) planes of SnS (for SnS the stacking direction is defined as the first index h in the hkl notation). However several exceptions are encountered, suggesting different in-plane orientations such as normal to (010) planes of SnS is parallel to the normal to (10.0) planes of SnS₂. In most cases, diffraction spots pertinent to (10.0) and/or (11.0) planes of SnS₂ and (011) or (010) of SnS coincide or almost coincide with the tubule axis. Thus the rolling vectors of the two subsystems can be determined as shown in FIG. 4.

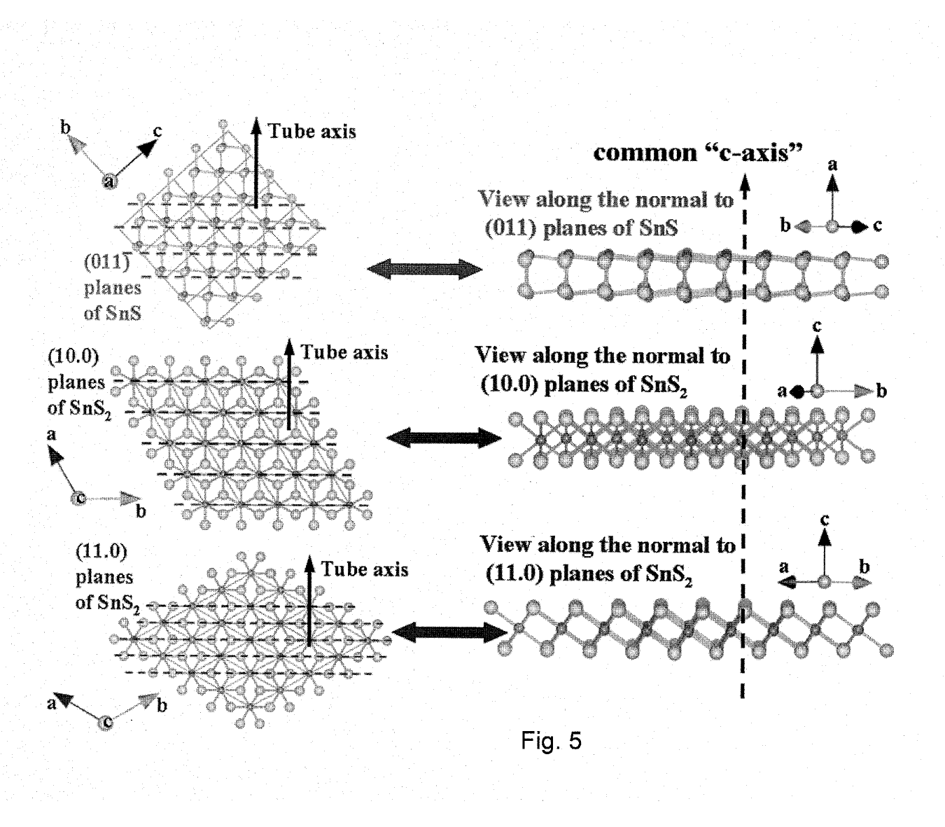

For SnS₂, the layer is called zigzag folded when 10.0 coincides with the tube axis, and armchair when 11.0. Coincidence of both 10.0 and 11.0 spots of SnS₂ with the tubule axis was also observed in tubules of different periodicities and implies different rolling vectors of the SnS₂ layers in the same tubule. Example of O-T-T tubule is shown in FIG. 5.

Helical arrangement of the SnS₂ and SnS layers in the tubules manifests itself through the different orientation of the atomic lattice on the upper and the bottom walls (relative to the substrate) of the tubule. Each of the top and bottom walls of a helical tube with a single helix angle will give rise to azimuthal splitting of the 11.0, 10.0 (of SnS₂) and 010, 011 (of SnS) spots.

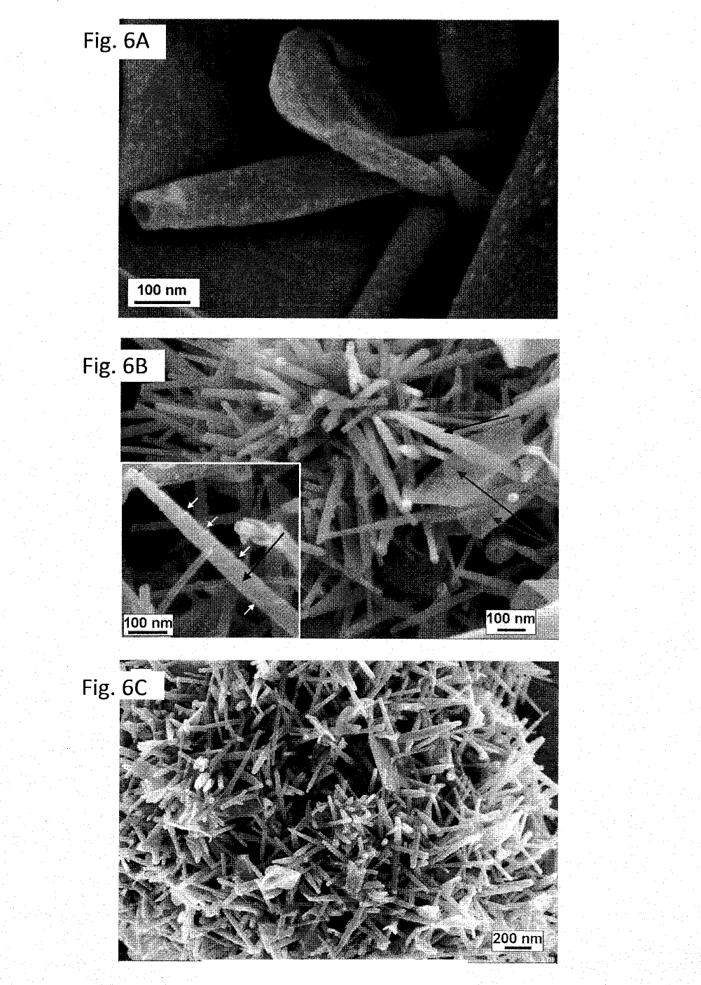

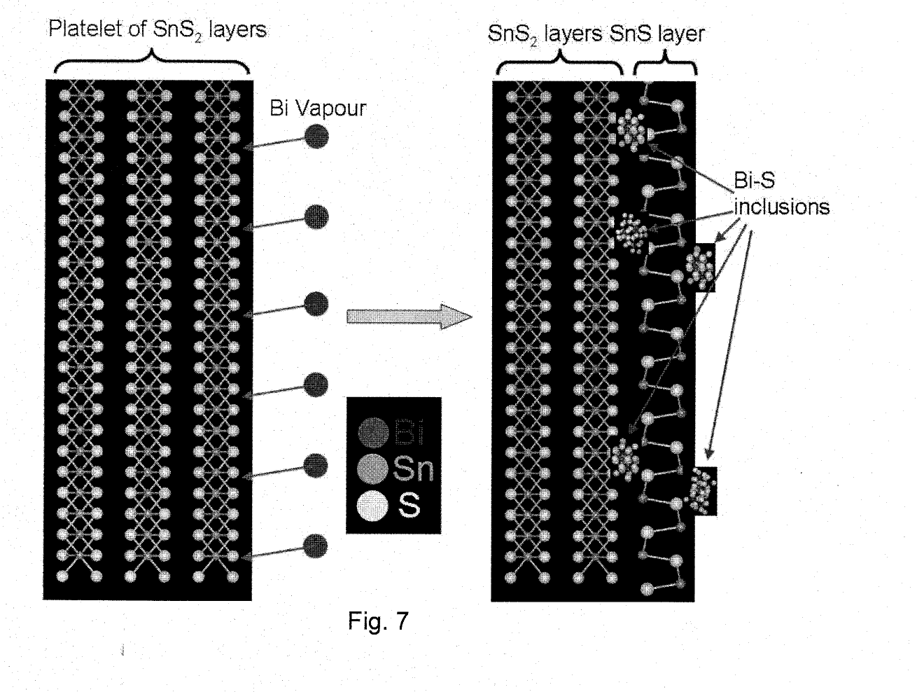

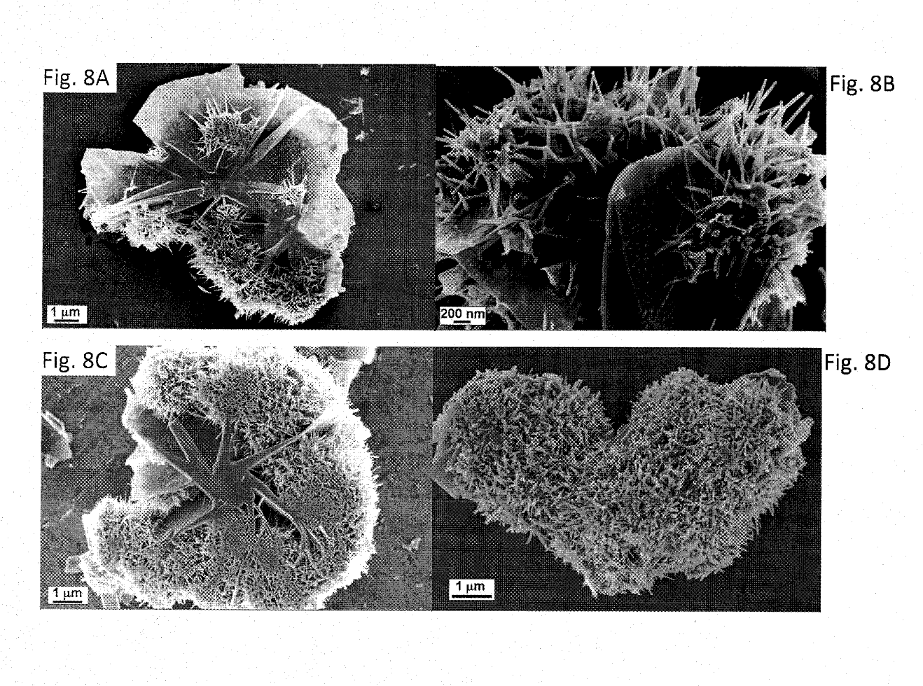

The SnS₂/SnS structures of the invention formed by the process of the invention, were analyzed in the transmission electron microscopy (TEM) and high resolution TEM (HRTEM) and can be classified to comprise of three main structured groups: (1) SnS₂/SnS ordered superstructure nanoscrolls and (2) nanotubes; (3) pure SnS₂ nanotubes. Their diameters range from 13-165 nm and the length from 90 nm to 3.2 μm. The number of layers varied from 3-40. Bending of the nanosheets produces nanotubes or nanoscrolls with several stacking order possibilities. The scrolling process characterized by scanning electron microscopy (SEM) of a few SnS₂/SnS molecular-layers sheet is shown in FIG. 6A and marked by red arrows in FIG. 6B. The gradual conversion of micrometric SnS₂ platelets into nanotubules via the catalytic action of Bi and Sb₂S₃ is demonstrated in FIGS. 7 and 8A-8D. By the end of the process the platelets are completely converted into either nanotubes, nanoscrolls and unscrolled nanosheets as can be seen in FIGS. 6C and 8D.

### EXAMPLES

SnS₂ (Alpha Aesar 99.5), Bi (Fluka 99.999), and Sb₂S₃ (Cerac/Pure 99.999%) powders were inserted into a quartz ampule at a molar ratio of 6:2:1 respectively. The total mass of the precursors was ˜20 mg. The ampule was sealed in a vacuum of ˜2×10−5 Torr and inserted into a horizontal 2-zone reactor furnace. The performed hightemperature annealing procedure involved two main steps: First a constant temperature profile of 780° C. for 2 h. Next, the ampule was subjected to a temperature gradient of 780-190° C. for 1.5 h, and was of the ampule.

For the synthesis of the conical tubules (see below), SnS₂ (Alpha Aesar 99.5%) and Nb (Acros Organics 99.8%) powders were inserted to a quartz ampule at a molar ratio of ˜1.5:1 respectively. The ampule was sealed at a vacuum of ˜2×10−5 Torr and inserted into a vertical 1-zone reactor furnace. The performed high-temperature annealing procedure involved two steps: First, the ampule was kept at a temperature gradient of 830° C. at the bottom (with the precursors) and 50° C. at the upper edge for 1.5 h. Next, the ampule was moved inside the furnace and subjected to a temperature gradient of 830° C. at the upper edge and 150° C. at the bottom. The product accumulated in the cold edge of the ampule. The ampule was removed from the furnace and cooled in plain air.

Preparation of the Samples to Electron Microscopy.

The analysis herein is based on scanning electron microscopy (SEM), transmission electron microscopy (TEM), and electron diffraction (ED) within the TEM. Carbon/collodion-coated Cu TEM grids and SEM stubs based on Si/Al substrates were prepared by dripping several droplets from a suspension of the product in EtOH. The resulting samples were examined by TEM, Philips CM120 operating at 120 kV, equipped with energy dispersive X-ray spectroscopy (EDS) detector (EDAX-Phoenix Microanalyzer) for chemical analysis, and high resolution TEM-HRTEM (FEI Technai F30-UT) with a field-emission gun operating at 300 kV. Scanning electron microscopy (SEM), Zeiss Ultra model V55 and LEO model Supra 55VP equipped with EDS detector (Oxford model INCA) and backscattering electron (BSE) detector were utilized.

Results

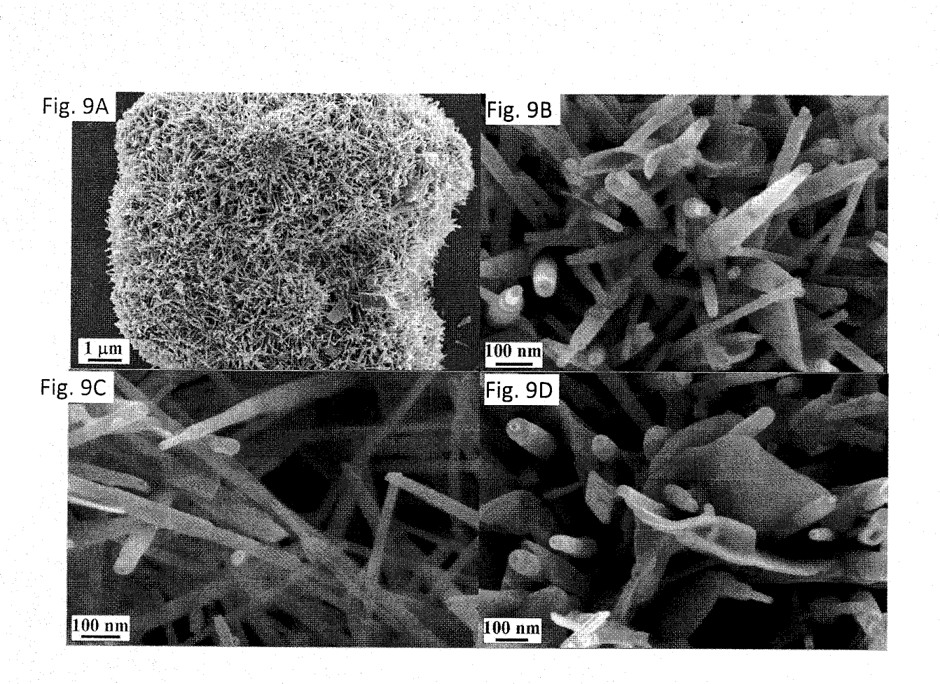

The growth mechanism of the “misfit” nanotubular structures, their surface morphology, and their chemical analysis were elucidated by the SEM and TEM. FIG. 9A shows a “hedgehog” like agglomerate of SnS₂/SnS tubular crystals. The hollow core of many tubules can be clearly seen in the high magnification images in FIGS. 9B-9D. Several scroll like tubes with growing steps are clearly seen in addition to straight ones, which are usually thinner. The outer diameter of the straight tubules ranges between 20 and 60 nm, while that of the stepped ones can reach up to 160 nm. Tubules with a helical wound growth step can be clearly seen in FIGS. 9B-9D. Here, a slab of several SnS2 and SnS layers is wrapped into a cylindrical scroll. The edge of the slab describes a helical path on the surface of the tubule which is reminiscent of the NbS₂/PbS “misfit” scroll. FIG. 9D shows several tubules in a process of scrolling.

Internal Structures. The interplanar spacing of the basal planes (00.1) of α-SnS2 is 0.59 nm and that of (200) α-SnS is 11.18/2=0.56 nm. (In SnS, each unit cell consists of two corrugated tin sulfide double layers). Note that for α-SnS, the stacking of the layers, that is, the axis perpendicular to the basal plane is represented by the index “h” in the hkl notation (aaxis). Note also that in the hexagonal system hk.l is equivalent to the notation hkil with i=−(h+k). In the majority of cases, ordered superstructure tubules with asymmetric layer stacking of (O-orthorhombic) SnS, and (Ttrigonal) SnS2 in a sequence O-T . . . could be observed with lattice spacing of 1.15 (0.56+0.59) nm or O-T-T . . . with lattice periodicity of ˜1.74 (0.56+0.59+0.59) nm along the common “c-axis”. Tubes with a periodicity of O-T-O-T-T . . . with lattice spacing of 2.89 (0.56+0.59+0.56+0.59+0.59) nm were also encountered, albeit rarely. Tubes having random stacking order were also sporadically encountered.

The periodicity of the superstructure can be determined from the diffraction patterns, that is, from the distance between two adjacent basal reflections of order “n” and “n+1”. Intuitively, as the “d” spacing of the superstructure increases, the distance between the “n” and the “n+1” spots decreases. Table 1 classifies the presented tubules in this paper according to their internal structure.

TABLE 1
List of the Tubular Structures
Discussed in the Present Work

| tube | | | |
|---|---|---|---|
| number | figure | periodicity | comments |
| 1 | 3 | | tubule with partly unrolled |
| | | | superstructured sheet |
| 2 | 4 | O-T | highly strained-wavy fringes |
| 3 | 5 | O-T-T | |
| 4 | 6 | O-T-O-T-T | |
| 5 | 7 | | abrupt growing steps |
| 6 | 8 | O-T-T | view down the tube axis |
| 7 | 9 | O-T-T | conical tubule |
| 8 | S2 | O-T | highly strained-wavy fringes |
| 9 | S3 | T | pure SnS₂ tubule |
| 10 | S4 | O-T-O-T-T | |
| 11 | S5 | | varying stacking order tubule |
| 12 | S6 | | wound growing step |

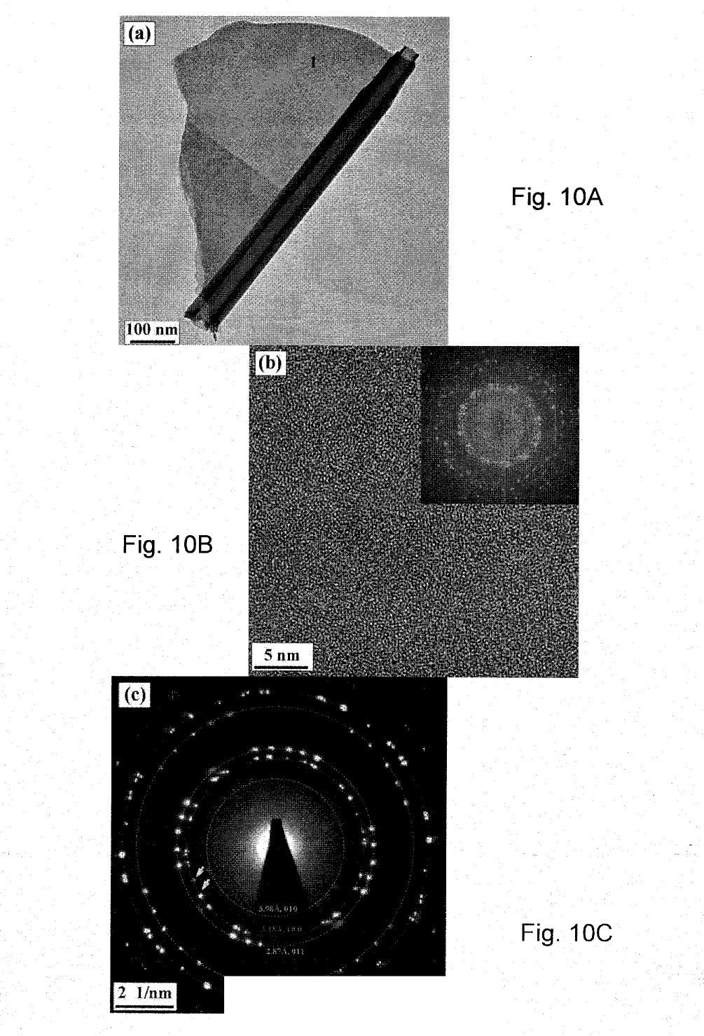

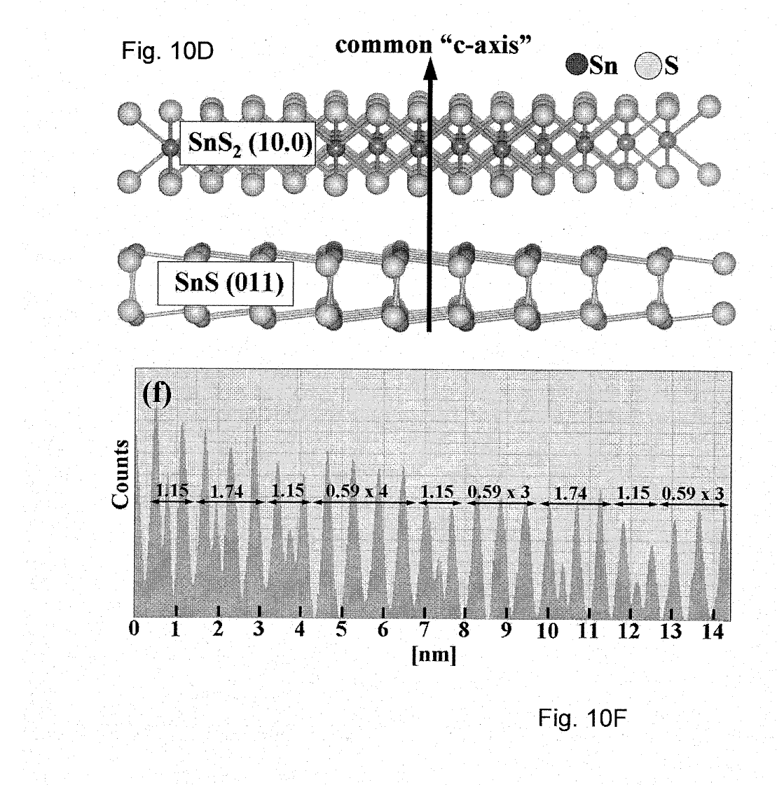

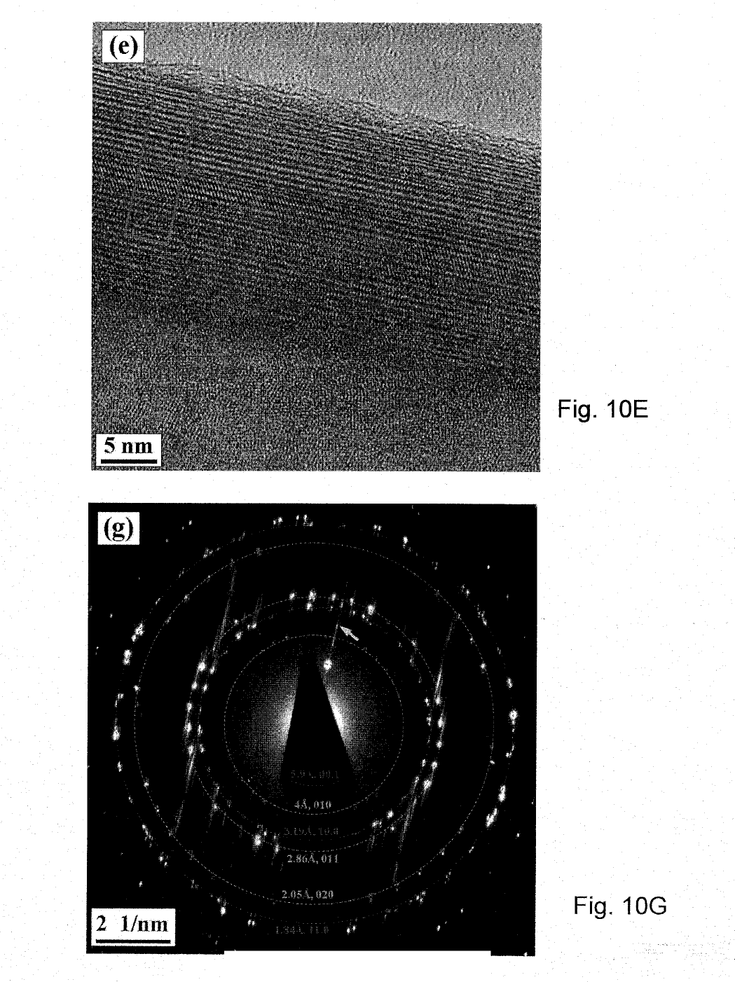

FIG. 10A shows an example of a tubule, which is not fully rolled. The SAED of the planar sheet can be more readily analyzed and help corroborate the structure of the nanotube itself.

First, the structure of the unrolled sheet (area “1” in FIG. 10A) is analyzed. FIG. 10B shows a high magnification image of the sheet at area “1” with its fast Fourier transform (FFT) in the inset and its diffraction pattern as shown in FIG. 10C. The sheet consists of several layers of SnS₂ and SnS. The diffraction pattern shows a series of close spots at equal distances from the undiffracted beam forming almost ring-like patterns. It is noticed that the 10.0 pattern of the SnS₂ sheets (appropriate red circle) is azimuthally matched to the 011 pattern of the SnS ones. It can be therefore concluded that the two layers are stacked together with the common normal to the (10.0) plane of SnS₂ and (011) plane of SnS (see FIG. 10D). This interlocking order, which is designated by (O-T) is relevant in the majority of the nanotubes reported in this work. The ring-like patterns of these diffraction spots are produced by the different orientation of the (O-T) slabs with respect to the common “c-axis” reminiscent a turbostratic structure. Furthermore, some diffraction spots of the 10.0 circle (see yellow arrows) are not paired with respective 011 of SnS planes. This phenomenon suggests (see below) that the sheet contains also individual SnS₂ (T) layers stacked between the O-T slabs along the common “c-axis”.

It is important to realize that the planar form of the sheet allows one to unequivocally assign the 2.89 Å spots to the (011) plane (interlayer spacing 2.93 Å) rather than the (111) plane (2.83 Å) of SnS. The (111) plane forms an angle of ˜75.33° with respect to the (100) basal plane of SnS (14.67° with respect to the common “c-axis”) and hence its diffraction is impossible. The angle between the (100) and (011) is indeed 90° making the diffraction of the (011) plane plausible.

Similarly, the rolled part (area 2 shown in FIG. 10C) of this nanostructure consists of both SnS and SnS2 layers; however, their stacking is not periodic and more complex than suggested by the analysis of the sheet (FIGS. 10B, 10C). This irregularity is clearly seen in the line profile in FIG. 10F. Randomly distributed O-T, O-T-T stacking as well as several grouped T layers are clearly observed. The diffraction pattern taken from the middle of the tubule (area “2” shown in FIG. 10G), shows a strong spot pertinent to lattice periodicity of 0.59 nm, which is assigned to the (00.1) planes of SnS2 with several higher order weaker spots. However, the stacking order of the T, O-T, and O-T-T units in this tube lacks periodicity. Therefore, no diffraction spots along the “c-axis” which are pertinent to the periodicities 1.15 (O-T) or 1.74 (O-T-T) nm are observed. Instead, the diffraction pattern along the “c-axis” is smeared (pointed by yellow arrow in FIG. 10G).

The measured interplanar spacings of both SnS2 and SnS layers inside the sheet (and also the tubule) are unchanged relative to the bulk counterparts within 3%, see Table 2. Therefore, unlike in the NbS2-SnS and NbS2-PbS systems, it is believed that in the SnS2-SnS “misfit” system, both SnS2 and SnS almost retain their original bulk structure upon stacking. In contrast to the NbS2-SnS and NbS2-PbS “misfit” systems (see above), in the case of SnS2-SnS, the misfit occurs along two axes of the basal planes. The lack of a commensurate direction along which the tubule axis is expected to coincide, has large influence on its growth axis. This incommensuration leads to a production of tubules with different folding vectors (orientations along the tubule axis) and in-plane orientation of the two subsystems. However, as would be shown, in the majority of the cases the normal to the (10.0) planes of SnS2 is parallel to the normal to the (011) planes of SnS (O-T coupling), and both normals roughly coincide with the tubule axis.

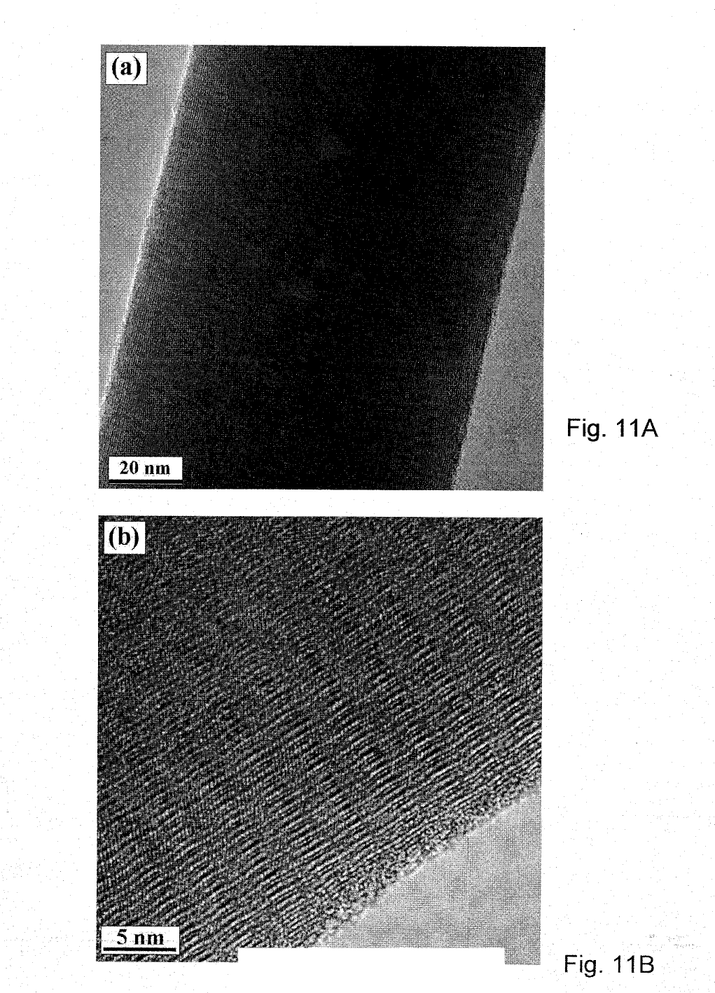

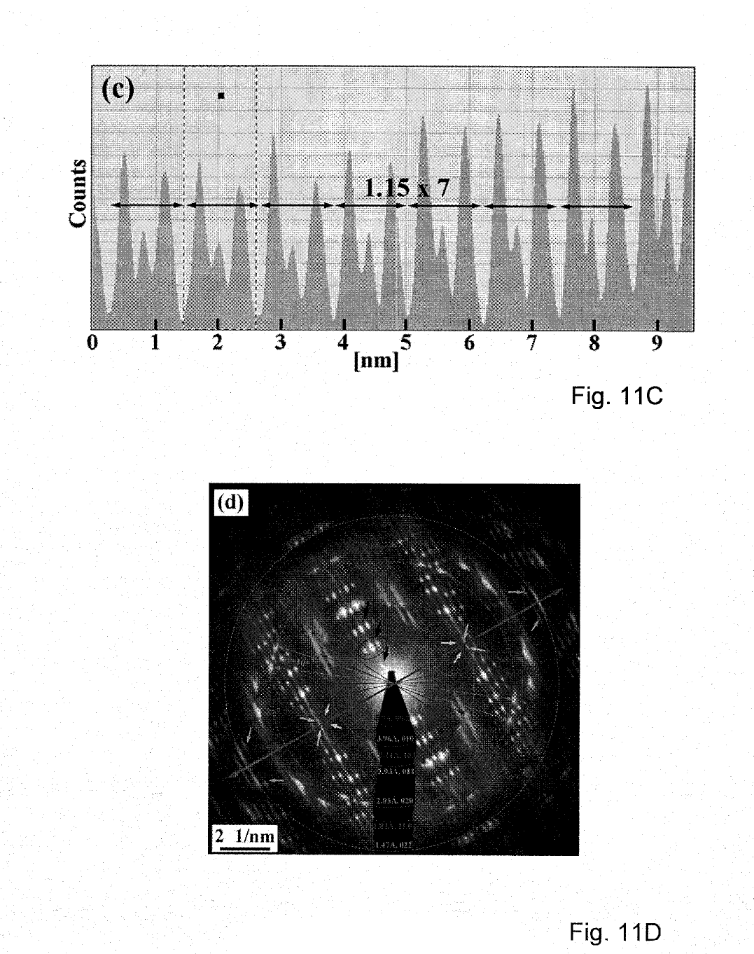

FIGS. 11A and 11B show an example of a tube with O-T ordered superstructure with 1.15 nm periodicity along the “caxis”. The line profile of this O-T tube is shown in FIG. 11C. The consequent array of 00n spots pertinent to the basal planes of the superstructure is marked by blue arrows on the diffraction pattern in FIG. 11D. (Here the basal planes of the superstructure would be represented by the index “1” in the hkl notation). The spacing between two consequent (001) spots in the reciprocal space corresponds to 1.15 nm in the real space and is in agreement with the periodicity shown in the line profile shown in FIG. 11C. The interplanar spacings of 3.96 and 2.03 Å are marked by green rings and are assigned to the (010) and (020) planes of SnS. (Note that for SnS, the axis perpendicular to the basal planes is represented by the index “h” in the hid notation). According to the data based on X-ray diffraction (XRD) ICSD collection code 24376,10 the interplanar spacing of (020) is 1.99 Å; however, no XRD peak is noted for (010). It is clearly seen that the 020 spots are located at the same azimuthal angle as the 010 reflections which are streaked and relatively weak. These different order spots are observed on the same azimuth (and marked by appropriate green circles in FIG. 11D). It is quite common that certain reflections in the electron diffraction pattern, like the 010 of SnS, are absent from the XRD patterns. The interplanar spacings of 3.14 and 1.82 Å are assigned to the (10.0) and (11.0) planes of SnS2 (red circles) which is in agreement with the values of bulk single crystal.

The cylindrical shape of the tubules leads to the 2 mm symmetry for the diffraction pattern where 2 and the first m is along the tubule axis and the second m is along the direction perpendicular to the tubule axis.

Streaks perpendicular to the tubule axis (pink double arrow) occur at most spots in the diffraction pattern. This arises from the cylindrical shape of the tubules. The translational stacking disorder of the c-layers (or a-layers for SnS) affects the reflections. The translational disorder is a direct consequence of the differences in circumference of successive cylinders. For both (10.0) and (11.0) of SnS₂ there are six sets of doubly splintered spots, which is in agreement with the multiplicity factor of 6 for both these planes (see Table 2).

TABLE 2
Interplanar Spacings and Multiplicity
Factors of Bulk SnS₂ and SnS^{a}

| plane | interplanar | multiplicity |
|---|---|---|
| indices | spacing [Å] | factor |
| SnS₂ {00.1} | 5.891 | 2 |
| SnS₂ {10.0} | 3.1567 | 6 |
| SnS₂ {10.1} | 2.7824 | 6 |
| SnS₂ {10.2} | 2.1536 | 6 |
| SnS₂ {11.0} | 1.8225 | 6 |
| SnS₂ {11.1} | 1.7411 | 6 |
| SnS {200} | 5.59 | 2 |
| SnS {011} | 2.9307 | 4 |
| SnS {111} | 2.8349 | 8 |
| SnS {020} | 1.991 | 2 |

^{a}Data for bulk SnS₂ and SnS was taken from the ICSD collection codes 42566²⁰ and 24376¹⁰, respectively.

Two of the six couples of the 10.0 spots of SnS2 (appropriate red circle), are oriented along the tube axis (see yellow arrows). Therefore the tubule axis of the SnS2 layers of that nanotube is roughly oriented along the [1010] direction of SnS2 (similarly to MoS2 nanotubes). A small chiral angle which is not seen from the 10.0 spots because of the heavy streaking, can nevertheless be seen from the splitting of the second order 20.0 spots as marked by orange arrows. Similarly for SnS, two of its 011 couples of spots are parallel to the tubule axis (marked by cyan arrows). Therefore, the axis of the tube coincides with the normal to (011) planes of SnS and is also normal to the (10.0) of SnS2. As discussed before, this configuration is relevant to most of the nanotubes observed in this study. However, in a few percent of the tubules the normal to the (010) planes of SnS coincides with the normal to the (10.0) planes of SnS₂ and with the tube axis.

The O-T tubes almost invariably show “wavelike fringes” and some periodic shades perpendicular to the tube axis, as marked in FIGS. 11A, 11B by the red arrows.

Consequently the basal reflections (perpendicular to the tube axis) in the diffraction pattern are splintered as marked by the blue ellipse in FIG. 11D. The splitting appears for every order “n” of the basal reflections as shown in FIG. 11D. The distance between the splintered “subspot” to the “main” in the reciprocal space corresponds to the spacing (˜3.5 nm) between the shades (wave periodicity) in the real space image as shown by the red arrows in FIGS. 4a and 4b. This behavior was mostly observed for the O-T tubes and much more rarely for the O-TT or O-T-O-T-T nanotubes. It is believed that O-T tubes suffer the highest strain since the amount of misfit between the layers per unit volume exceeds that of the other two stacking types. Thus this may be one of the stress relaxation mechanisms.

The helical arrangement of the SnS₂ and SnS layers manifests itself through the difference in the orientation of the atomic lattice on the top and the bottom walls of the tubule. Each of the top and bottom walls of a helical tube with a single helix angle will give rise to splitting of the 11.0, 10.0, 010, 011 spots of SnS₂ and SnS, respectively. The chiral angle can be estimated from the splitting of the mentioned reflections in the diffraction pattern, and equals half the angle of the azimuthal splitting of the spots. The chiral angle of the SnS₂ layers was determined from the azimuthal splitting of the 11.0 sets as marked by red double arrows in FIG. 11D and was found to be ˜6°. Surprisingly, a quite different value is obtained from the splitting of the 10.0 spots and equals ˜5°. The small difference in the calculated chiral angles emerges from the smearing of the diffraction spots. For SnS, a value of ˜5° was obtained from the splittings of the four sets of the 010 reflections and their second order 020 spots as marked by green double arrows in FIG. 11D. The multiplicity factor for the {020} planes in bulk SnS is 2.

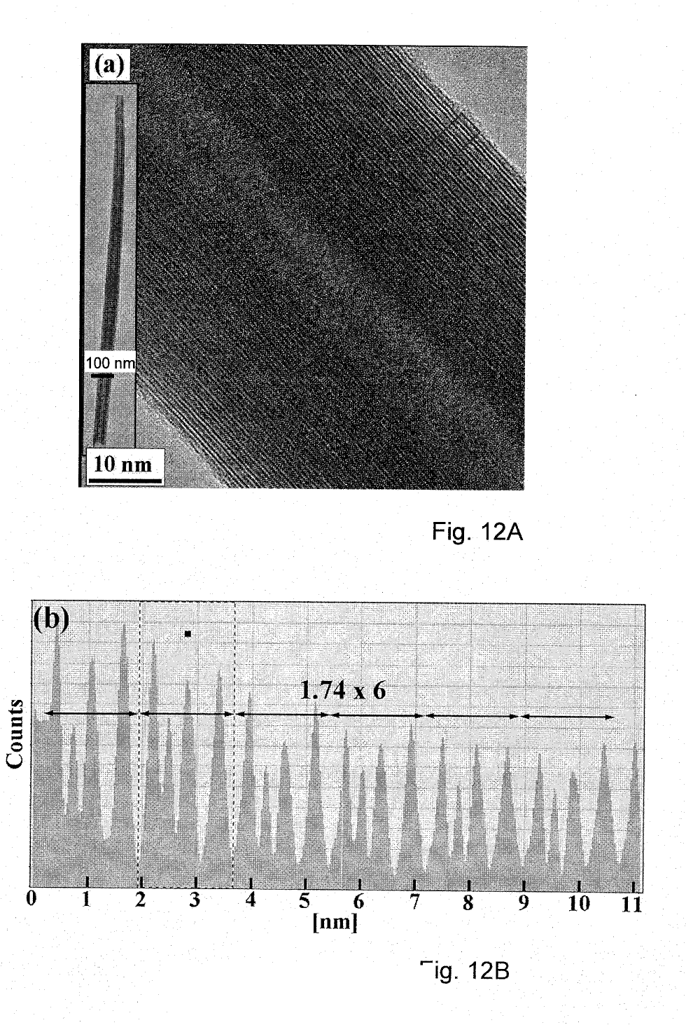

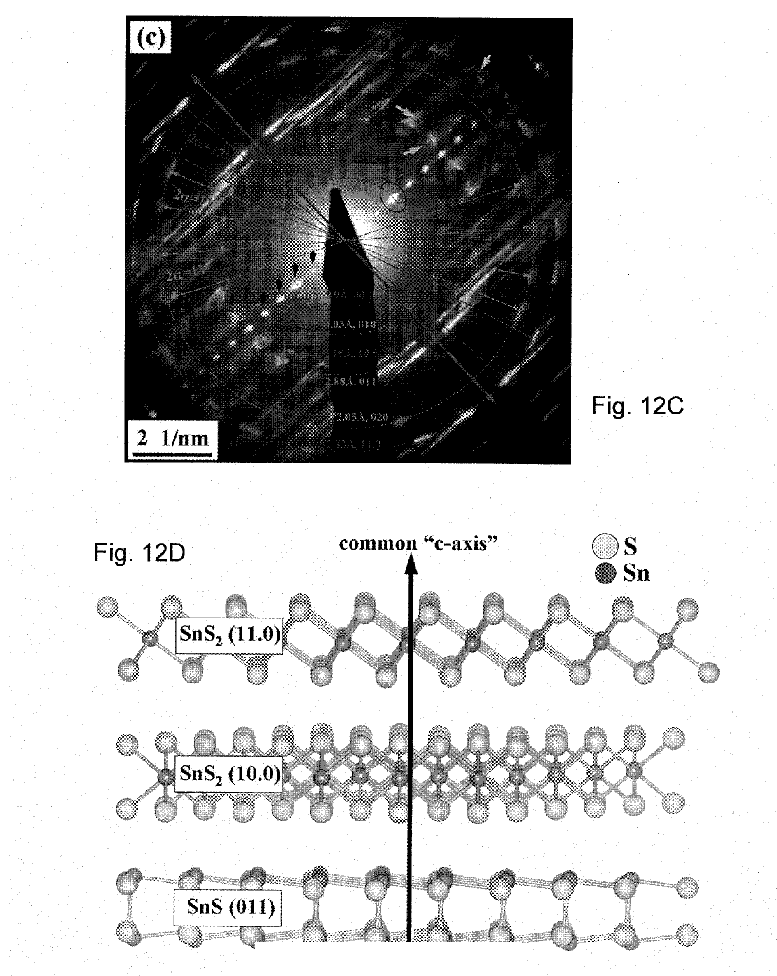

FIG. 12A shows an example of a O-T-T tubule with 1.74 nm periodicity along the “c-axis” as shown in the line profile in FIG. 12B.

The diffraction pattern clearly shows an array of 00n spots marked by blue arrows in FIG. 12C (first order is covered under the central beam). The space between two consequent spots in the reciprocal space is equivalent to 1.74 nm in the real space and in agreement to the periodicity shown in the line profile in FIG. 12B. The interplanar spacings of (10.0) and (11.0) planes of SnS2 and (010) and (011) of SnS, are indicated on the diffraction pattern (FIG. 12C). They are all in good agreement with values of bulk SnS2 and SnS single crystals within 3% deviation. Such a deviation can be attributed to variation of the interplanar distances because of strain, but also to the measurement errors of the distances between the spots. Every two adjacent layers of SnS₂ in the O-T-T superstructure, produce a clear diffraction spot 00.1 along the common “c-axis” which is pertinent to interplanar spacing of 0.59 nm. This diffraction spot is particularly strong because accidentally, the third order reflection 003 of the O-T-T superstructure, 1.74/3=0.58 nm, coincides with the 00.1 reflection of SnS₂.

In the current tube both the 11.0 and 10.0 diffraction spots of the SnS₂ (T) are close to coincident with the tubule axis (pink double arrow). Also, there are 12 equally splintered sets of 10.0 and 11.0 spots of SnS₂ while the multiplicity factor of both planes is 6. Such an observation suggests the occurrence of two different rolling vectors of the layers within the same tubule. All 12 sets of spots are splintered by the same angle and two of them are marked by red double arrows as shown in FIG. 12C. Pure SnS2 tube is shown in the Supporting Information, FIG. S3 for comparison. Here too, the diffraction of the (11.0) and (10.0) planes are splintered each into 12 couples of chirally splintered spots. It is not clear from the diffraction pattern (FIG. 12C) if the different rolling vectors of the SnS2 planes (T) occur within the same O-T-T slab or in different slabs. However, the intensity of the 11.0 and 10.0 diffraction spots is approximately similar, suggesting the same number of SnS2 walls with different folding vectors. This observation hints that the different folding vectors of SnS2 (T) layers occur within the same O-T-T slab which shown schematically in FIG. 12D. Similarly to the previous examples, the diffraction spot 10.0 of SnS2 azimuthally coincides with the 011 of SnS in the O-T-T tubule (FIG. 12C). The chiral angle for SnS2 layers was determined from the azimuthal splitting of 11.0 sets as marked by red double arrows in FIG. 12C and was found to be ˜6°. Splitting of the 10.0 spots leads to the same angle. Eight sets (4+4) of 010 and 020 spots of SnS appear; however, half of them correspond to chiral angle of 5.5° and half to 6.5° as marked by green double arrows in FIG. 12C.

Close examination of the 11.0 and 10.0 sets of spots of SnS2 and 011 of SnS in FIG. 12C reveals closely splintered (six) spots (marked by yellow arrows) along the azimuthal direction which are also streaked along the “c-axis” (perpendicular to the tube axis). The azimuthal splitting of the 11.0 10.0 and 011 into 6 spots and their streaking along the “c-axis”. It should be emphasized that the splitting of the azimuthal angle occurs for both SnS2 and SnS reflections. In the case of the SnS2 walls, the azimuthal 6-fold splitting is seen for the 11.0 and 10.0 reflections. For the SnS walls the 010, 020, and the 011 reflections are splintered into 6 points. Such a splintering suggests a scroll structure of the tubule. However, a closer analysis is needed to elucidate the relationship between the azimuthal splitting of the spots and the scrolling process of the nanotube.

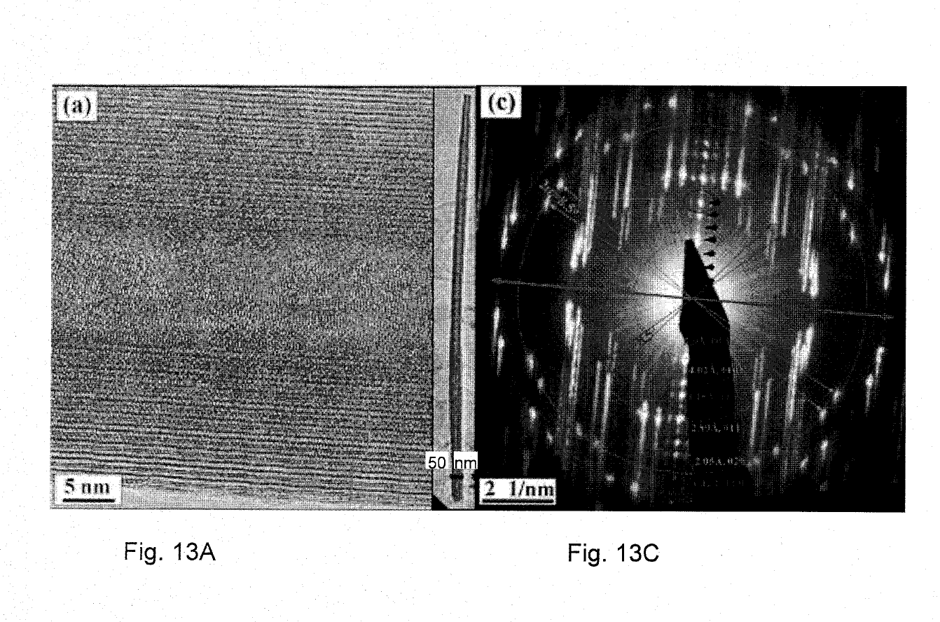

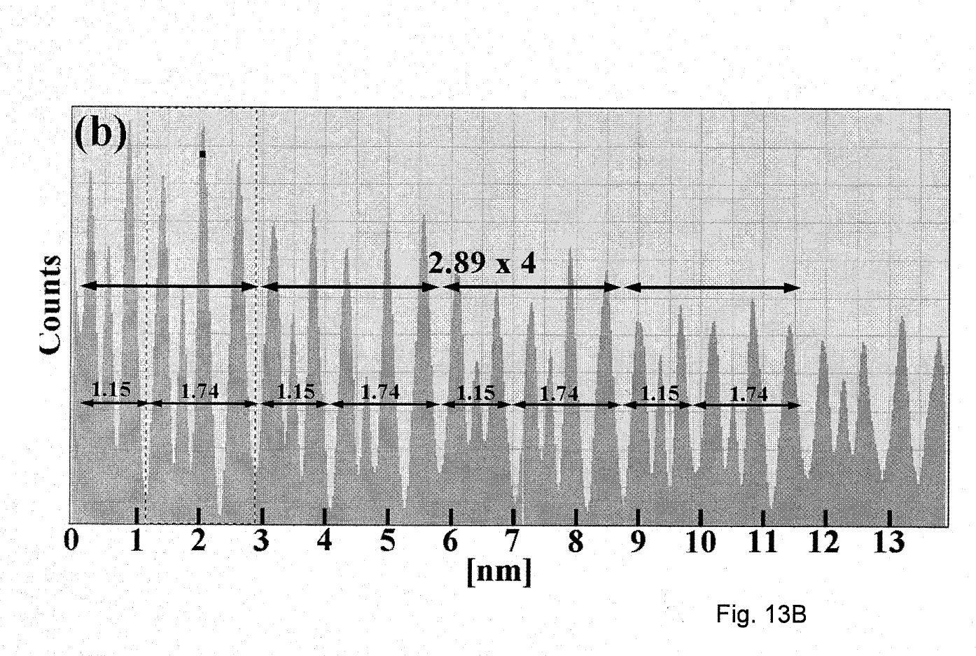

FIG. 13A shows an example of O-T-O-T-T ordered superstructure tubule with a “c-axis” periodicity of 2.89 nm as shown in the line profile in FIG. 13B. The diffraction pattern clearly shows an array of very closely spaced 00n spots along the “c-axis” of the superstructure. The first four orders, which are marked by ascending blue arrows from the center, are covered under the central beam. The spacing between two 00n adjacent spots in the reciprocal space in FIG. 13C is equivalent to 2.89 nm in real space (FIG. 13A) and is in agreement with the periodicity shown in the line profile in FIG. 13B. The measured values of interplanar spacings of both SnS and SnS2, like (011) and (11.0), respectively, are noted on the patterns and are in a good agreement with the bulk values within 3% deviation. Similarly to the O-T-T tube (FIG. 12), every two adjacent SnS2 layers produce a clear diffraction 00.1 spot along the common “c-axis” which agree with the interplanar spacing of 0.59 nm. This diffraction spot is particularly strong because accidentally, the fifth order reflection 005 of the O-T-O-T-T superstructure, 2.89/5=0.578 nm, coincides with the 00.1 reflection of SnS2. In analogy to the previous examples, both the 11.0 and 10.0 spots of SnS2 almost coincide with the tubule axis, and 12 couples of equally splintered spots of 11.0 and 10.0 are observed as well as 8 sets of 010 and 020 of SnS with equal azimuthal splitting. As in previous tubules, the 10.0 of SnS2 is parallel to the 011 of SnS.

The chiral angle of the SnS2 layers was determined from the splitting of 10.0 and 11.0 spots and was found to be ˜4.3°. The same value for the splitting (chirality angle) was obtained for the 010 and 020 spots of the SnS. Additional example of an OT-O-T-T tube.

The stress relaxation in SnS/SnS2 superstructure nanotubes manifests itself in different ways. One mechanism pertinent mostly to the O-T tubes is the appearance of the wavy structure along the axial direction (see red double arrows in FIGS. 11A, 11B) and the satellites of the basal reflections in the diffraction pattern (see blue ellipse in FIG. 11D). These satellites exist also, though they are appreciably fainter for O-T-T and O-T-O-T-T tubes (marked by blue ellipse in FIGS. 12C, 13C). Another stress relaxation mechanism occurs in the O-T-T and in O-TO-T-T stackings as shown in FIG. 5. This stress relaxation mechanism, is the fine azimuthal splitting of the 10.0, 11.0, and 011 spots (yellow arrows) in FIG. 12C and the more clearly visible splitting of the 10.0, 11.0 spots of SnS2 and the 010, 020, and 011 of SnS. This splitting was attributed to the scrolling of the tube walls.

Tubes with varying stacking order along the “c-axis” were also encountered. Stacking periodicity may vary also along the tubule axis by creation of edge dislocation-like defects.

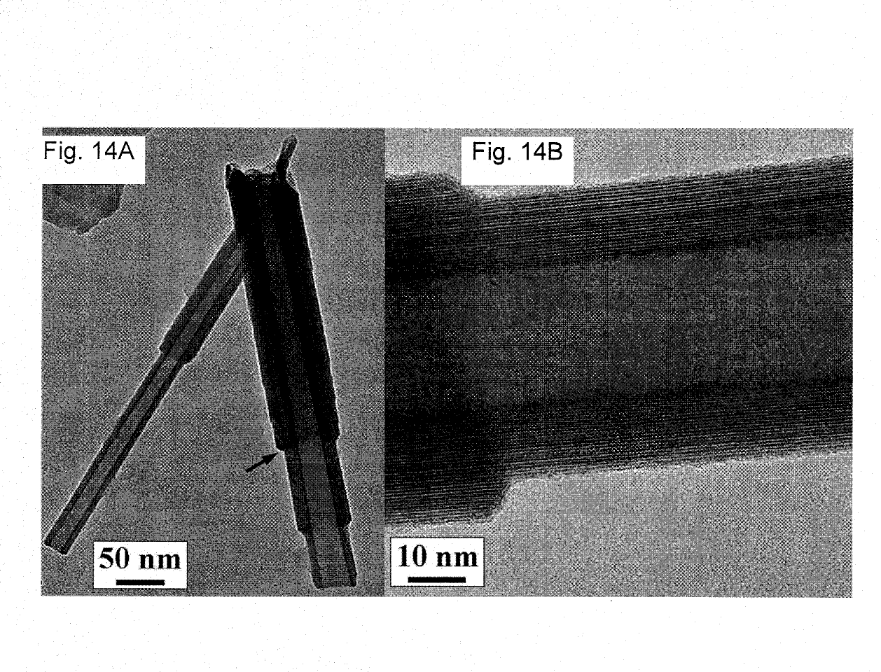

Generally, tubes with outer diameters larger than ˜60 nm often exhibit growing steps with varying outer diameter as shown in SEM micrographs in FIGS. 2b-d. Tubes with constant outer diameter larger than 60 nm are also encountered, albeit rarely. FIGS. 14A-14B shows a TEM image of tubules with growing steps. Such steps may arise from the scrolling of a nonrectangular “supersheet” shape as shown in FIGS. 9D, 10A.

It is also possible that a preformed thin tube with constant outer diameter of 20-40 nm serves as template for further scrolling of additional strained superstructure sheets. The outer diameter of the tubules showed in FIGS. 7A-7B changes abruptly; however, chiral wound envelopes are also often encountered. Multistep nanotubes with varying outer diameter have also been observed in the case of chrysotile.

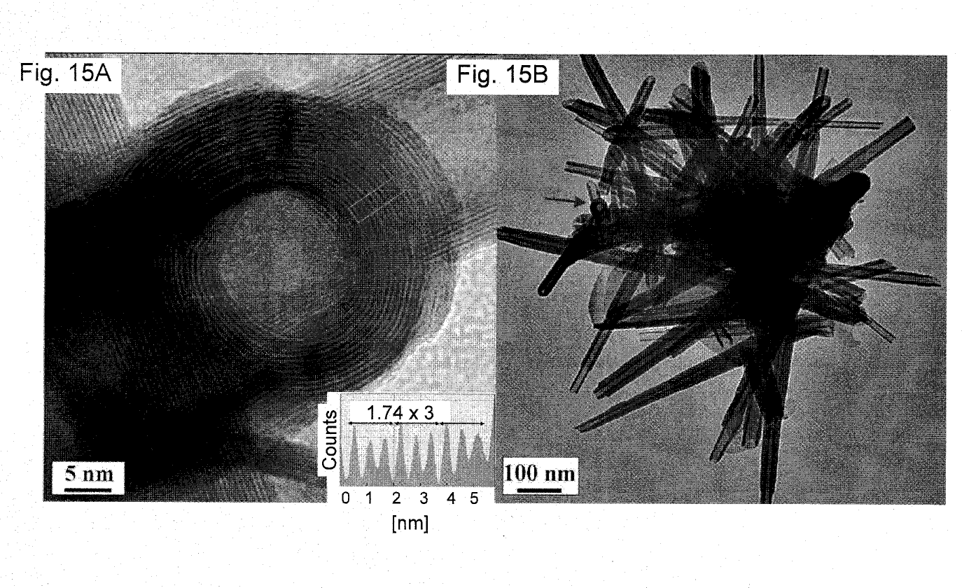

FIG. 15A shows a cross section view of a beam-parallel standing O-T-T nanoscroll. This standing tubule is part of a small tubular agglomerate shown in FIG. 15B. Growth step is apparent at the right side. Unfortunately, the proximity of the scroll to other tubules prevents obtaining an independent diffraction pattern from it.

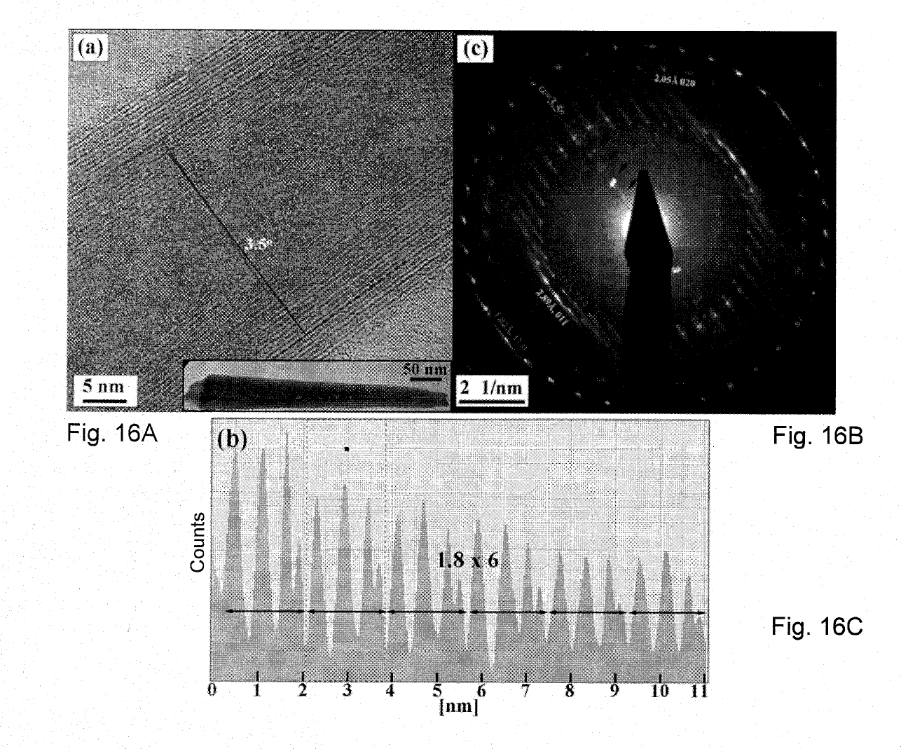

Conical tubules are also encountered. These were produced mainly while Nb was used as a catalyst. FIG. 16A shows an example of such a scroll with T-T-O ordered superstructure as shown in the line profile in FIG. 16B. In the diffraction patterns of conical tubules, the main basal spots consist of two equispaced linear arrays of relatively sharp spots (marked by blue segmented lines in FIG. 16C). These spot pairs coalesce at the origin. Their azimuthal angle equals the projected apex angle of the cone.

The line of symmetry between the two arrays is parallel to the cone axis. The angle of the cone can be determined from the diffraction patterns as shown in FIG. 16C by the azimuthal splitting of the basal reflections which is about 3.5° in the present case. Slight increase in the interplanar spacings of about 1-3% is observed for the SnS₂ and SnS layers of the conical vs cylindrical tubules. The value of the “c-axis” periodicity of the conical T-T-O superstructure is ˜18 Å and is slightly larger than the original 17.4 Å of the cylindrical O-T-T nanotube (FIG. 12) as can be easily verified in the line profiles (FIGS. 12D and 16B) and diffraction patterns (FIGS. 12C, 16C).

Conclusions

The tubular structures of the SnS₂/SnS misfit compound were studies by HRTEM and electron diffraction. These tubes were produced in large amounts as previously described4 using a variety of metallic catalysts. Most of the tubes show ordered superstructure with precise stoichiometry of (SnS)_{1.32}(SnS₂), (SnS)_{1.32}(SnS₂)₂, and [(SnS)_{1.32}]₂[(SnS2)]₃. However, tubules with random stacking have been also encountered. The periodicity of the superstructure can be determined from the distance between two adjacent basal reflections of order “n” and “n+1” in the diffraction pattern. Extensive statistical structural analysis performed on a large amount of the tubules, suggests that in all cases both SnS2 and SnS layers have a common “c-axis”. As for their in planar orientation, in most cases the normal to the (10.0) planes of SnS2 is almost parallel to the normal to the (011) planes of SnS (for SnS the stacking direction is defined as the first index h in the hkl notation). However several exceptions are encountered, suggesting different in-plane orientations such as when the normal to (010) planes of SnS is parallel to the normal to (10.0) planes of SnS2. Analysis of the relatively thick unrolled SnS2/SnS superstructure sheet (FIG. 10) suggests that the various coupled SnS2-SnS superstructure sheets are often differently oriented along the common “c-axis” which leads to 11.0, 10.0 diffraction spots of SnS2 and 010, 011 of SnS to form almost ring-like patterns. However, it is not clear if such stacking disorientation is random in the tube and further analysis is required. In several cases, spots pertinent to (10.0) or (11.0) planes of SnS2 and (011) or (010) of SnS are parallel or almost parallel to the tubule axis. Thus the rolling vectors can be easily determined. For SnS2, the layer is called zigzag folded when 10.0 coincides with the tube axis, and armchair when 11.0. Coincidence of both 10.0 and 11.0 spots of SnS2 with the tubule axis was observed and implies different rolling vectors of the layers in the same tubule. Helical arrangement of the SnS2 and SnS layers in the tubules manifests itself through the different orientation of the atomic lattice on the upper and the bottom walls (relative to the substrate) of the tubule. Each of the top and bottom walls of a helical tube with a single helix angle will give rise to splitting of the 11.0, 10.0 (of SnS2) and 010, 011 (of SnS) spots.

Annealing of Sns₂-Sns Ordered Superstructure Tubules

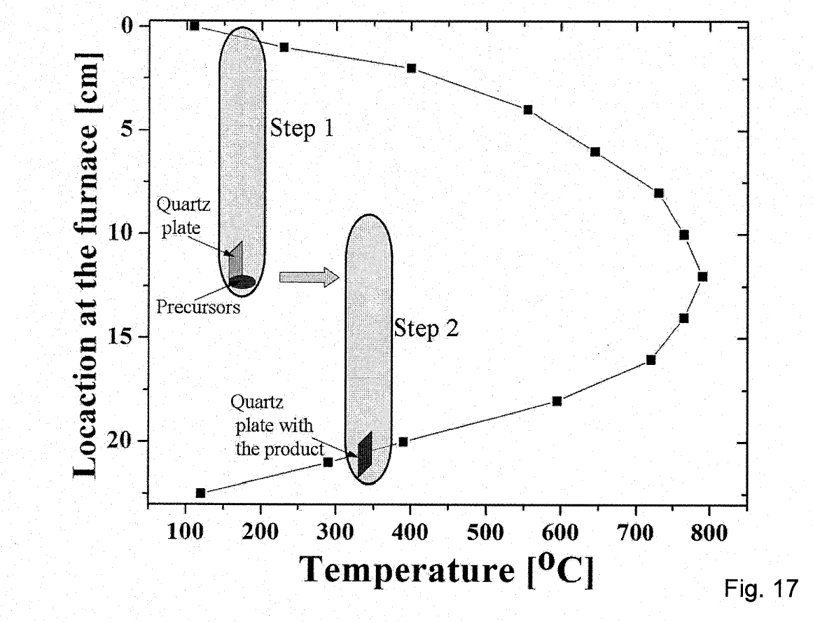

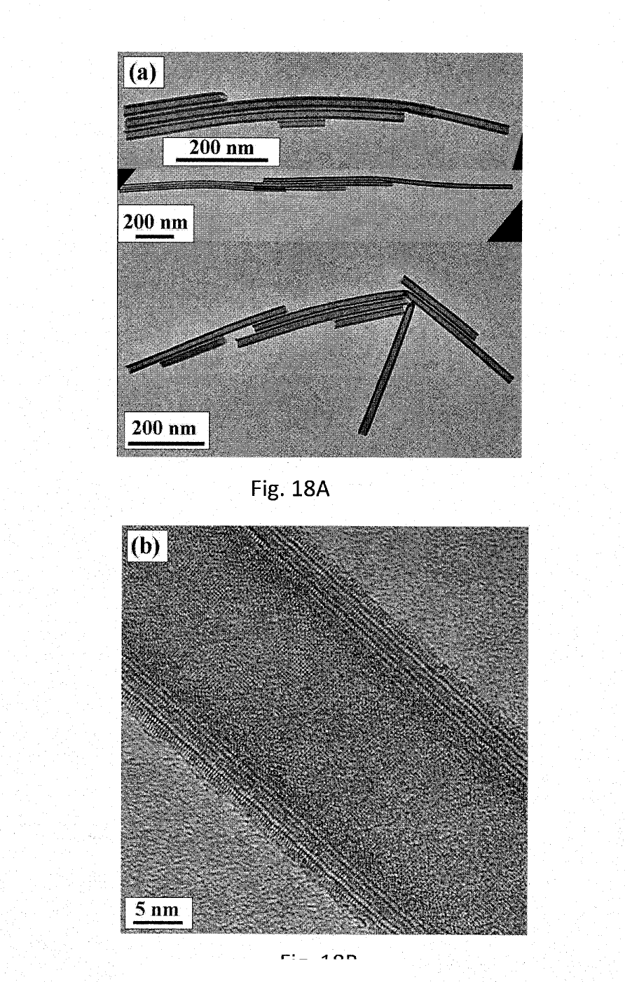

For the synthesis of the SnS₂—SnS tubular nanostructures, SnS₂ (Alpha Aesar 99.5%), SnS (Alpha Aesar 99.5%), Bi (Fluka 99.999) and Sb₂S₃ (Cerac/Pure 99.999%) powders were inserted to a quartz ampoule at a molar ratio of ˜6:2:2:1 respectively. To facilitate the collection of the desired product, a small quartz plate (1 cm×1 mm area) was inserted to an ampoule and was kept at an edge. The ampoule was sealed at a vacuum of ˜2×10⁻⁵ torr and inserted into a vertical 1-zone reactor furnace. The performed high-temperature annealing procedure involved two steps as shown in FIG. 17. First: the ampoule was kept at a temperature gradient of ˜790° C. at the bottom (with the precursors) and ˜110° C. at the upper edge for 1 h. Next, the ampoule was moved inside the furnace and subjected to a temperature gradient of ˜790° C. at the upper edge and ˜150° C. at the bottom for 50 minutes. The product accumulated at the bottom cold edge of the ampoule with a big part being deposited on a quartz plate as shown in FIG. 17. The ampoule was removed from the furnace and cooled at plain air. Such a vertical configuration yields a similar product to the previously described horizontal analogue, however, within a shorter time. After the synthesis, the ampoule was open and the quartz plate was inserted to another ampoule. The ampoule was sealed under vacuum of 2×10⁻⁵ ton and was kept at 320° C. for 20 hrs. Carbon/collodion-coated Cu TEM grids were prepared by touching the quartz plate. The resulting samples were examined by TEM, Philips CM120 operating at 120 kV, equipped with energy dispersive X-ray spectroscopy (EDS) detector (EDAX-Phoenix Microanalyzer) for chemical analysis, and high resolution TEM-HRTEM (FEI Technai F30-UT) with field-emission gun operating at 300 kV. The vast majority of the annealed tubular structures were straight, and thin as shown in FIG. 18. Typical length of the tubes ranges between 150 nm and 1.5 μm. The high resolution images show the high degree of perfectness and the lack of dislocation like defects as shown in FIG. 18B.

Synthesis in a Flow System

General Aspects

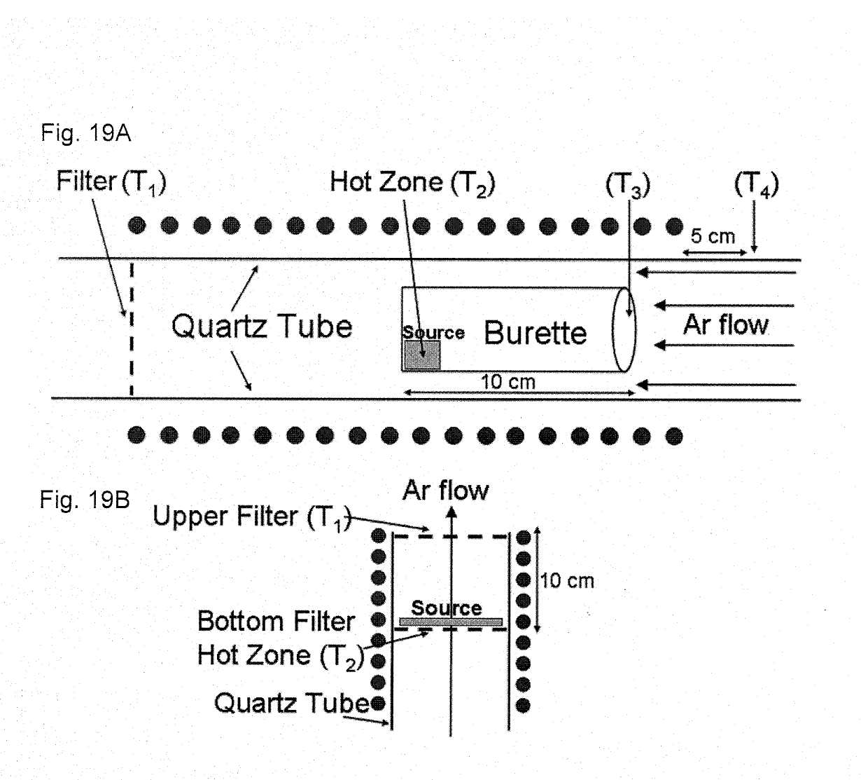

The scaling-up of the nanotubes synthesis can be realized in a flow reactor. Achieving a proper temperature gradient and the material transfer along this path must be carefully considered here. The synthesis was first attempted in a horizontal reactor and later-on in the vertical configuration as described below. In both cases the tubes obtained in a flow system (few experiments only) were much thinner and shorter than those obtained in the closed ampoules. These nanotubes showed typically a diameter which varied from 13-47 nm, and a length of 90-300 nm. Also, the tubes were straight and no nanoscrolls were observed in the product of the present flow reactors, as shown in FIGS. 19A-19B. It is believed that the main growth mechanism in this case can be regarded as the VLS process. This mechanism is widely described in and the principles can be implemented here. It is suggested that hot bismuth vapor cools through collisions with the buffer gas, and condenses into liquid nanoclusters. The nanotube growth begins after the liquid bismuth droplet becomes supersaturated with respect to SnS₂ and/or SnS and continues for as long as the Bi—Sn—S nanocluster remains in a liquid state and the Sn—S reactant remains available. The growth terminates when the nanotubes leave the hot zone of the reactor. The internal structure of the nanotubes (pure SnS₂ or SnS₂/SnS ordered superstructure) can be controlled via the different flow rates of the carrier gas as described below.

The influence of the different growth parameters on the produced nanostructures may vary in different methods, probably due to the different growth mechanisms. For example, addition of Sb₂S₃ in addition to Bi in a sealed ampoule drastically increased the yield of the tubular structure production; however, when it was used in a flow system the yield of the nanotube production was drastically decreased, and nanowhiskers were the main product. EDS examination of such whiskers indicated the presence of Sn, Sb, Bi and S at a ratio close the known phase of Sn₂Bi_{0.3}Sb_{1.7}S₅.

Synthesis in a Horizontal Flow Reactor—Experimental

SnS₂ was mixed with Bi (at a ratios similar to the ratios in the sealed ampoules) with or without small additions of SnS and/or Sb₂S₃ powders (see schematic rendering of the reactor in FIG. 19A). The mixture was inserted into a small quartz burette measuring 16 and 18 cm in the inner and outer diameter, respectively, and 10 cm in length. The powder mixtures were concentrated at the closed edge of the burette. The burette was then placed into a horizontal quartz reactor with an inner diameter of 26 mm, which was inserted into a single zone furnace and was initially kept out of the hot zone. Argon was used as a carrier and protecting gas and was run for 2 hr prior to the experiment in order to remove any oxygen or water vapor from the reactor. The furnace was then heated until the hot area T₂ reached 730° C. The source powder was then moved into a hot zone, while the gas flow was kept at ˜40 standard cubic centimeters per minute (sccm) and the system remained in this state for 1.5 hr. The burette was aligned in such a way that the flow direction of the evaporated product, due to the temperature gradient, was opposed to the flow of the carrier gas, as shown in FIG. 19A. This procedure allows the fumes to remain at the hotter edge for a longer period of time and promotes circulation between the hotter and the colder zones. The products accumulated at the upper side of the reactor in the low temperature zone T₄ (slightly above room temperature) due to the natural temperature gradient in the furnace. The gas flow continued until the furnace was cooled to room temperature, in order to avoid possible oxidation of the sulfide product.

In a second set of experiments, Ar flow was increased to ˜50 sccm, significant part of the vapor species were swapped towards the second cold zone T₁ (left in FIG. 19A) through the hot zone of the furnace. T₃ was measured to be ˜450° C. Consequently, most of the product accumulates on a Schott filter (N° 4) with an average pore size of ˜10 μm which was kept at T₁˜150° C. as shown in FIG. S8a and only a small part accumulated between T₃ and T₄ zones. The products were collected with a spatula and sonicated in dehydrated analytical ethanol for 5-10 min Samples for electron microscopy were prepared in similar way to the procedure described above.

Synthesis in a Vertical Flow Reactor—Experimental

A vertical reactor is potentially more suitable for the synthesis of nanoparticles in larger amounts. SnS₂ and Bi powders were mixed as previously described and were dispersed on a bottom quartz Schott sinter disk N⁰4, built inside a quartz tube with a 26 mm inner diameter as shown in FIG. 19B. The quartz tube was inserted into a single zone vertical furnace and the bottom filter was initially kept out of the hot zone. Ar gas was used as a carrier gas and was circulated for 2 hr prior to the experiment. The furnace was then heated, and when the hot area T₂ reached 650° C. the quartz tube was moved so that the bottom filter on which the source powder was placed was located in the hot zone as shown in FIG. 19B. Ar flow was kept at ˜15 sccm and the system remained under these conditions for 2 hr. The product was collected from a removable upper Schott filter similar to the bottom one, which was kept at T₁˜100-150° C. during the synthesis and sonicated in analytical ethanol for 5-10 minutes. The procedure for the sample preparation for the EM analysis was similar to the procedure described above.

2.4 Analysis of the Structure of the Tubes Produced in a Flow System

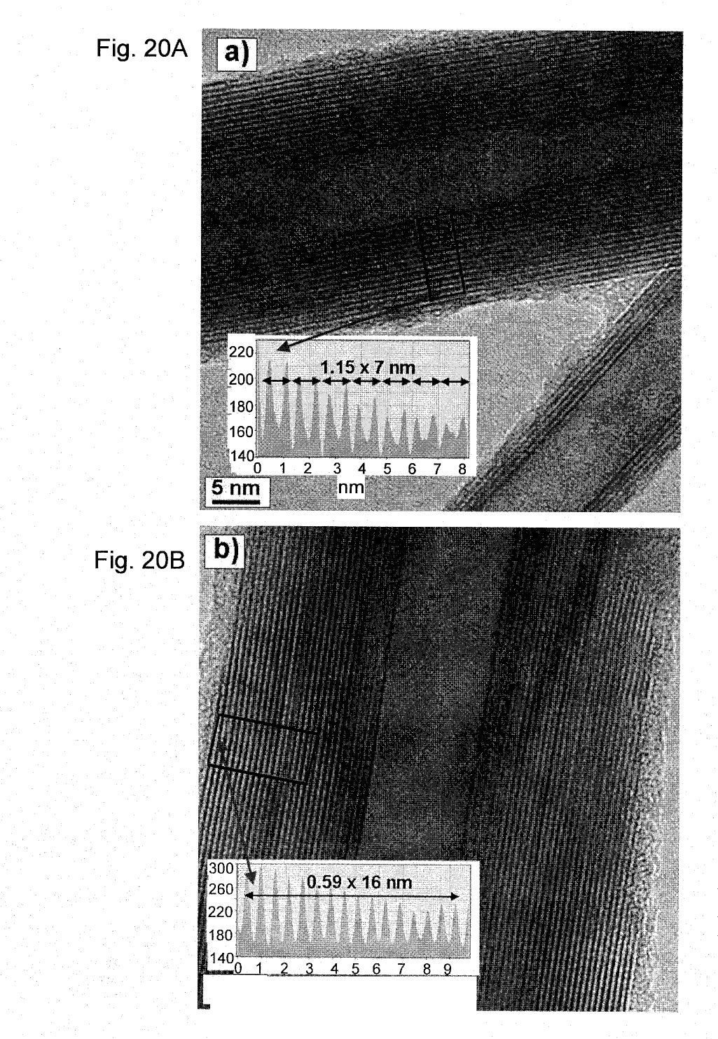

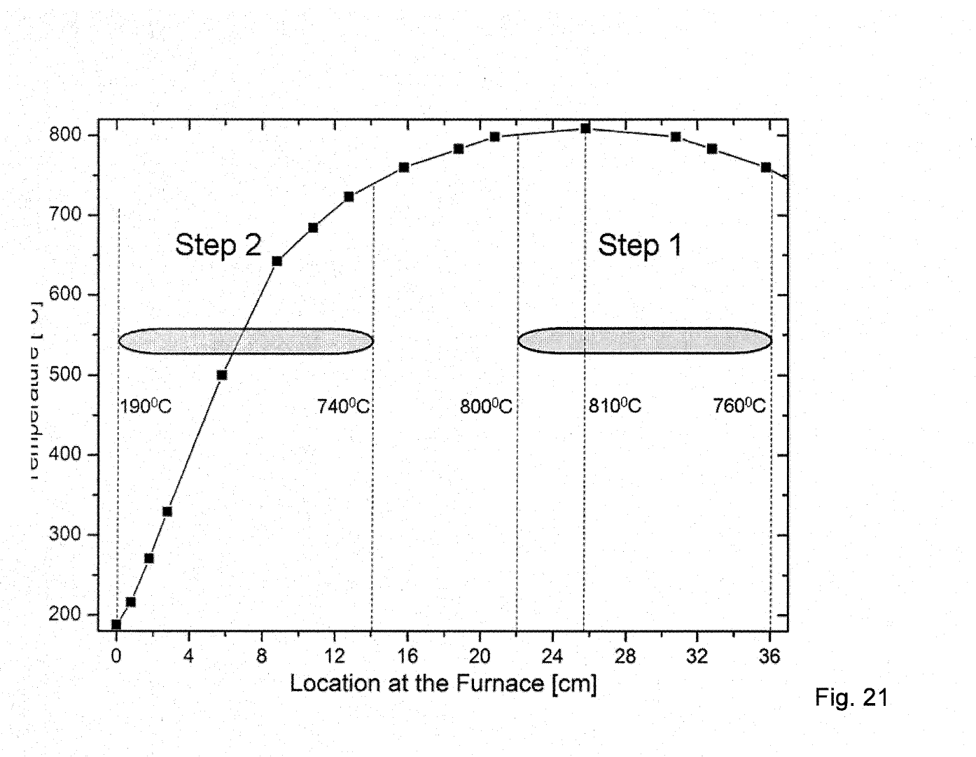

The products in the horizontal system were collected from the room temperature region T₄ on the upper side of the tube. It was also collected from the filter located at T₁˜150° C., on the opposite side of the hot zone. The relative amount of product collected from both sites was dependent on the Ar flow rate, as was described previously. The product which was collected from the T₄ area was found to consist of ordered superstructure nanotubes, mostly of O, T, O, T . . . superstructure with 1.15 nm periodicity as shown in FIG. 20A. However, examination of the product taken from the filter at T₁, resulted in almost pure SnS₂ nanotubes as shown in FIG. 20B. It is believed that repeated passing through the hot zone of the preformed SnS₂/SnS ordered superstructure tubules, acts as annealing and consequent conversion of sulfur deficient SnS₂/SnS ordered superstructures to stoichiometric SnS₂ layers.

Production of SnS₂/SnS Ordered Superstructure Tubules in a Sealed Ampoules with a Highest Yield

Quartz ampoules of 10 mm inner and 12 mm outer diameters were filled with SnS₂ (Alpha Aesar 99.5%) and Bi (Fluka 99.999%) powders. Small amounts of Sb₂S₃ (Cerac/Pure, incorporated 99.999%) powder was also added to the ampoules in several experiments. The molar ratio between SnS₂, Bi, Sb₂S₃ was ˜5:1:0.8 respectively. The ampoules were sealed in a vacuum of 2×10⁻⁵ torr and after the sealing their length was ˜14 cm. The ampoules were inserted into a horizontal 2-zone reactor furnace. The performed high-temperature annealing procedure involved two main steps as shown in FIG. 21. Step 1: almost constant temperature profile of 800° C. (with small deviations between the edges of the ampoule of no more then 50°) which was applied for 2 hrs. Step 2: the ampoule was moved inside the furnace and was subjected to a temperature gradient of 740-190° C. for 1.5 hrs, and was then cooled at plain air. The product accumulated in the cold zone of the ampoule.

Addition of Se to SnS₂/SnS Ordered Superstructure Tubules.

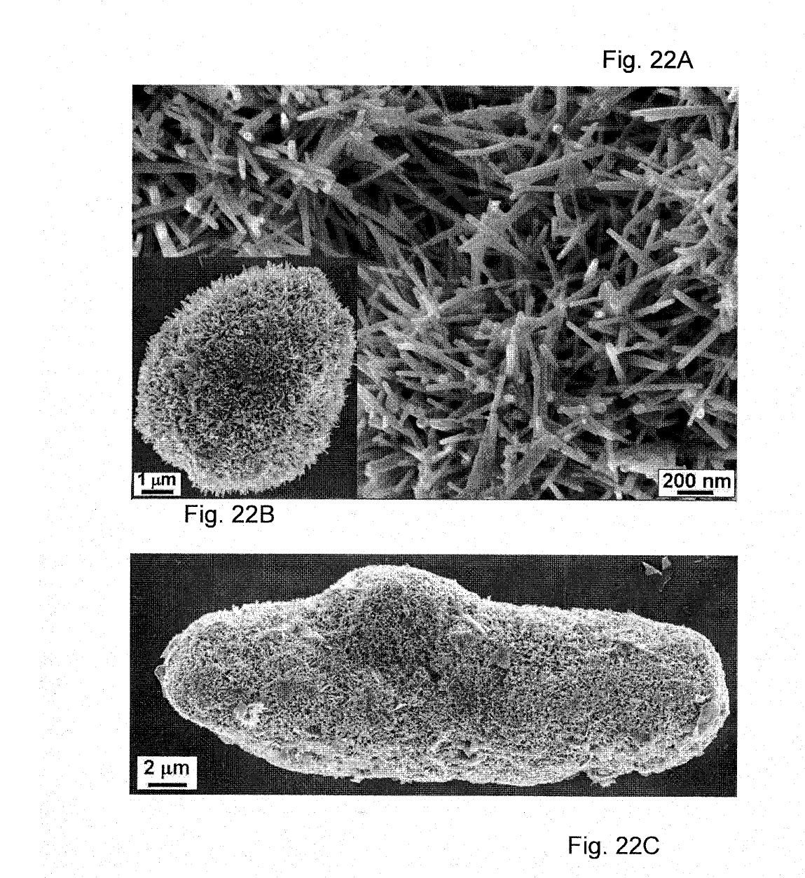

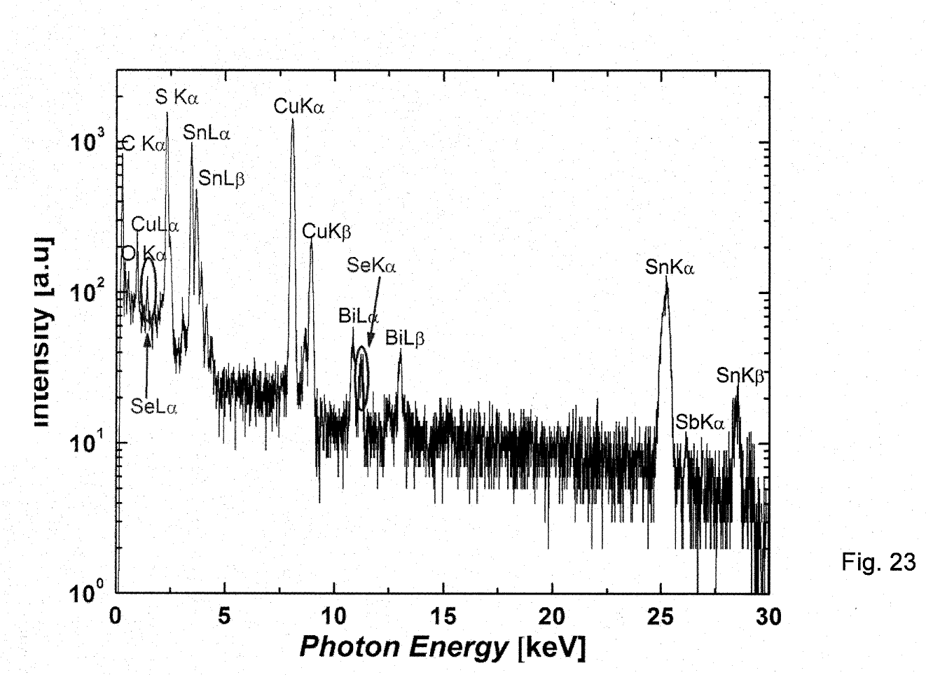

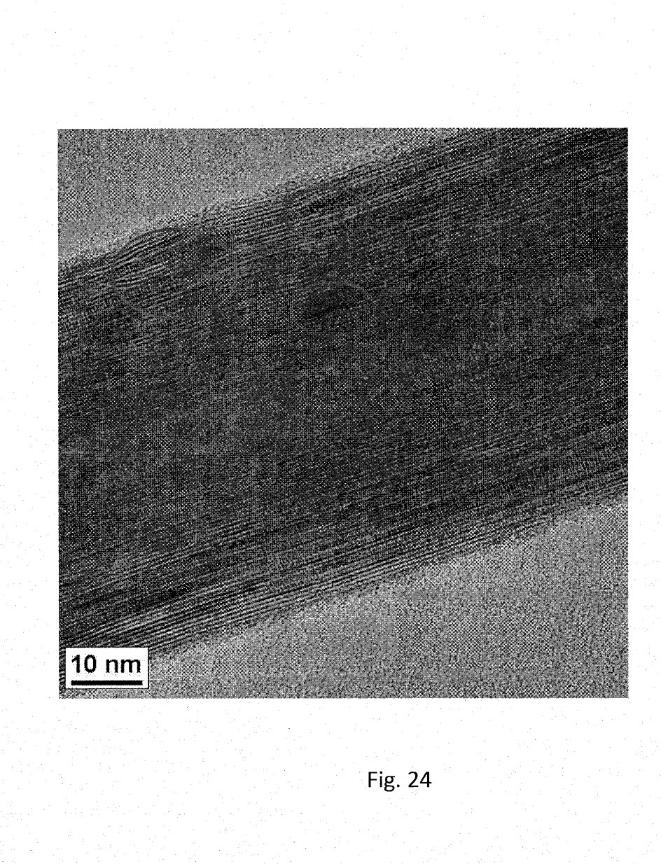

In several experiments in sealed ampoules, Sb₂Se₃ (Cerac/Pure 99.999) was used as a co-catalyst instead of Sb₂S₃, and a high yield of production was also obtained. Rest of the conditions remained the same. Similarly, large “hedgehog like” agglomerates of tubules were produced as shown in FIGS. 22A-22C. EDS examination of individual tubes indicated on presence of 1-2 percent of Se. Typical EDS spectrum is shown in FIG. 23. HRTEM examination of the tubes revealed that many of them exhibit almost perfect O-T-T or O-T ordered superstructure similar to mentioned previously when Sb₂S₃ was utilized as a co-catalyst. However, also some defected tubules are often encountered as shown in FIG. 24. These defects manifest mostly in variation of characteristic interplanar spacing, or insertion of extra layers reminiscent of an edge dislocation. The location of Se is still not completely understood, however, it may be possible that in a short range along the tubule axis, the SnS₂ or SnS layers are completely substituted by the SnSe₂ or SnSe ones respectively.

1.-27. (canceled)

28. A nanostructure, comprising:
ordered stacked sheets comprising
at least one first sheet of an inorganic layered compound of general formula MXₙ, and
at least one second sheet of an inorganic layered compound of formula M′Xₘ,
wherein M and M′ are each independently selected from a group consisting of Sn, In, Ga, Bi, Ta, W, Mo, V, Zr, Hf, Pt, Pb, Re, Nb, Ti, and Ru,
X is selected from S, Se, and Te;
n and m are each integers independently 1 or 2;
wherein said at least one first sheet and at least one second sheet have mismatched lattice structure.

29. The nanostructure according to claim 28, wherein
said at least one first sheet has the general formula (MXₙ)ₚ, wherein p is an integer selected from 1 to 5, and
said at least one second has the general formula (M′Xₘ)_{q}, wherein q is an integer selected from 1 to 5.

30. The nanostructure according to claim 28, having the general formula
[(MXₙ)ₚ(M′Xₘ)_{q}]ᵣ
wherein r is an integer selected from 1 to 100.

31. The nanostructure according to claim 28, wherein n=1 and m=2.

32. The nanostructure according to claim 28, wherein M and M′ are Sn.

33. The nanostructure according to claim 28, wherein X is S.

34. The nanostructure according to claim 28, wherein X is Se.

35. The nanostructure according to claim 28, wherein M and M′ are each independently selected from the group consisting of Nb, Sn, and Pb.

36. The nanostructure according to claim 28, wherein said sheets of an inorganic layered compound are closed sheets.

37. The nanostructure according to claim 28, wherein said sheets of an inorganic layered compound form a nanotube.

38. The nanostructure according to claim 28, comprising:
at least one first sheet comprising a inorganic layered compound of the formula MXₙ; and
at least one second sheet comprising a inorganic layered compound of the formula M′Xₘ,
wherein said sheets have mismatched lattice structure and are arranged in an ordered stacked configuration, thereby forming said nanostructure of the general formula (I):
[(MXₙ)ₚ(M′Xₘ)_{q}]ᵣ (I)
wherein M and M′ are each independently selected from a group consisting of Sn, In, Ga, Bi, Ta, W, Mo, V, Zr, Hf, Pt, Pb, Re, Nb, Ti, and Ru;
X is selected from S, Se, and Te;
each of n and m is independently 1 or 2;
each of p and q is independently selected from 1 to 5; and
r is an integer selected from 1 to 100.

39. An article, comprising at least one nanostructure comprising multiple ordered stacked sheets, as defined in claim 28.

40. The article of claim 39, selected from a transistor, a solar cell, an electrode, and a photo-catalyst.

41. A process for the preparation of a nanostructure comprising multiple ordered stacked sheets, as defined in claim 28, said process comprising:
providing at least one inorganic compound selected from MXₙ and M′Xₘ;
substantially vaporizing said at least one inorganic compound in the presence of at least one first catalyst at a vaporizing temperature (Tₐ); and
maintaining said vaporized at least one inorganic compound in a temperature gradient formed between a hot zone of temperature Tₐ and a cold zone of temperature T_{b} thereby forming said nanostructure in said cold zone.

42. The process according to claim 41, wherein said vaporization of said at least one inorganic compound is performed in the presence of at least one second catalyst.

43. The process according to claim 41, wherein said at least one inorganic compound is SnS₂, thereby forming a nanostructure of the formula
[(SnXₙ)ₚ(SnXₘ)_{q}]ᵣ
wherein X, n, m, p, and q are as defined.

44. The process according to claim 41, wherein X is selected from S and Se.

45. The process according to claim 41, wherein n=1 and m=2.

46. The process according to claim 41, wherein said Tₐ is in the range of from about 700 to 850° C.

47. The process according to claim 41, wherein said T_{b} is in the range of from about 300 to 100° C.
